(19) United States
(12) Patent Application Publication
(10) Pub. No.: US 2011/0020096 A1
(43) Pub. Date: Jan. 27, 2011

(54) Batch processing system in an in-line facility

(75) Inventor: Joachim Mink, Immendingen (DE)

Correspondence Address: TUE NGUYEN, 496 OLIVE AVE, FREMONT, CA, 94539, US

(73) Assignee: LOTUS SYSTEMS GMBH, Geisingen (DE)

(21) Appl. No.: 12/843,871

(22) Filed: Jul. 26, 2010

Related U.S. Application Data
(60) Provisional application No. 61/228,849, filed on Jul. 27, 2009.

(51) Int. Cl. H01L 21/677; B25J 11/00

(52) U.S. Cl. 414/222.01; 414/806; 257/E21.001

(57) ABSTRACT

Methods and apparatuses for a batch processing system with in-line interfaces are provided to batch processing substrates in an in-line processing facility. In an embodiment, the batch processing system comprises carrier assembling and carrier disassembling stations interfacing the in-line path and the batch processing stations.

This application claims priority from U.S. provisional patent application Ser. No. 61/228,849, filed on Jul. 27, 2009, entitled “Batch processing system”, which is incorporated herein by reference.

### FIELD OF THE INVENTION

The present invention relates to semiconductor processing, and particularly to batch processing of substrates for solar cell and flat glass applications.

### BACKGROUND OF THE INVENTION

Solar cell processing includes wet and dry processes on a substrate, such as a semiconductor substrate or a glass substrate. The wet processes include cleaning, conditioning, or wet deposition (plating or electroless plating). The dry processes include vapor deposition, high temperature anneal or doping.

Semiconductor fabrication facility typically comprises substrates stored in carrier boxes, for example, to be transported between process chambers. The carrier boxes can be transported by operators, or by an automatic transport system within the facility. For processing, the facility typically includes batch processing systems and single substrate processing systems.

In a batch processing system, multiple substrates are processed at the same time. FIG. 1A illustrates an exemplary carrier box 18 for carrying multiple substrates 13. The substrates are then transported 12B to a load port 10B, where the substrates 13 are loaded to a batch processing chamber 15B.

In a single substrate processing system, single substrates are processed individually. FIG. 1B illustrates a carrier box 18 carrying multiple substrates 13 to be transported 12C to a load port 10C. The substrates 13 are then loaded individually, for example, by a transport robot 19C to multiple single substrate processing chambers 15C.

In-line processing system is an alternative, typically for solar processing to provide low cost and minimal toxicity. In an in-line fabrication facility, substrates are transported continuously by a conveyor between processing chambers. The substrates also travel within the processing chambers during processing. For example, in a typical in-line annealing process, the substrates travel continuously from an in-line conveyor belt to a hot zone furnace. The throughput of the in-line process is determined by the speed of the conveyor belt, and for long processing time, a long process chamber (e.g., large foot print system) is needed to ensure adequate process environment.

FIG. 1C illustrates an exemplary prior art in-line processing system, comprising a loading station 10 and an unloading station 11 sandwiching a process station 15. A continuous movement mechanism 12, such as a conveyor belt, carries the substrates 13 to be processed from the loading station 10 to the process station 15 and out to the unloading station 11. Heaters 17 are arranged to anneal the substrates 13 in the process station 15. The throughput of the in-line system is typically determined by the speed of the conveyor belt, so that the substrates 13 are continuously processed in the processing station 15 at a predetermined rate. The length of the processing station 15 is thus proportional to the process time and the conveyor speed, and therefore for a long substrate process, the foot print of the in-line system can be large.

To reduce the length of the process chamber 15, multiple substrates can be placed parallel on the conveyor belt for parallel processing, reducing the conveyor speed, and thus the length of the process station. However, the width of the stations increases proportionally, and thus the system foot print does not change.

### SUMMARY

The present invention relates to a batch processing system, for example, employed in processing solar cell substrates. In an embodiment, the present batch system interfaces with in-line loading and/or unloading stations, to reduce system foot print for processes having long processing time. The exemplary batch system comprises a carrier assembly station for assembling the substrates from the in-line loading station onto a batch carrier, a batch processing station for processing the multiple substrates on the batch carrier, and a carrier disassembly station for disassembling the substrates from the batch carrier to the in-line unloading station. The present batch processing system can significantly reduce the system foot print, typically by the number of substrates in the batch carrier. The overhead time of substrate assembling and substrate disassembling can be reduced with multiple batch carriers so that when one carrier is processed, another carrier is assembled or disassembled. In an embodiment, the present batch system comprises a batch processing station interfacing with an in-line loading station, a batch processing station interfacing an in-line unloading station, or a batch processing station interfacing with an in-line loading station and an in-line unloading station.

In an embodiment, the batch processing system is a wet process system, for cleaning and/or electro or electroless deposition.

In an embodiment, the present invention discloses a carrier assembly station, assembling substrates coming from an in-line loading station to a batch carrier, which then can be transported to a batch processing station. The carrier assembly station can comprise a robotic mechanism, such as a multi-axis robot, to pick up substrates from the in-line station and to place substrates in a batch carrier. The in-line loading station preferably comprises sensors or an aligning mechanism to ensure precision picking from the robot mechanism. For a wet process, the substrates are preferably assembled in vertical positions in the batch carrier, for example, to prevent fluid turbulence when entering or leaving the liquid process tank.

In an embodiment, the present invention discloses a carrier disassembly station, disassembling substrates from the batch carrier to an in-line unloading station. After completing processing, the substrates in the batch carrier moves from the processing station to the carrier disassembly station so that the substrates can be transferred to an in-line conveyor belt to be carried to the next processing system. The carrier disassembly station can comprise a robotic mechanism, such as a multi-axis robot, to pick up each substrate from the batch carrier and to place each substrate on the in-line conveyor belt of the in-line unloading station.

In an embodiment, the present invention discloses a robotic mechanism for transferring substrates between the in-line station and the batch carrier. The robotic mechanism can comprise an end effector for supporting a substrate. In an aspect, the end effector comprises a vacuum mechanism for holding the substrate, especially when moving the substrate to a non-horizontal position. For example, the substrates can be assembled in vertical positions in a batch carrier, and thus the end effector can pick up the substrate from the horizontal position at the in-line station, and rotate to a vertical position before sliding the substrate in the batch carrier.

In an embodiment, the end effector further comprises a plurality of safety hooks to prevent the substrate from sliding off or falling off if the vacuum mechanism fails, especially in the non-horizontal position. The safety hooks preferably do not touch the substrate, but merely cover the substrate at a distance. In an aspect, the safety hooks are located outside the substrate area, and comprise a mechanism to move inward for protecting the substrate. In another aspect, the safety hooks are located inside and under the substrate area, and comprise a mechanism to move forward, outward and inward for protecting the substrate.

In an embodiment, the present invention discloses a batch carrier for holding multiple substrates. The batch carrier comprises a frame for supporting the substrates, and a number of slots for separating the substrates. The slots can be provided at two opposite sides, such as at the bottom and the top of the substrates. At each side, there can be multiple slots. The substrates can be positioned horizontally or vertically in the batch carrier, with vertical locations preferable for wet processes. In addition, for wet processes, the batch carrier can be made with metal frame for supporting strength, together with a plastic cover for operation in a corrosive or damaging environment. The batch carrier can also comprise a handling mechanism, for example, for a robotic mechanism to move the carrier from station to station. The carrier can be designed to accommodate large substrates, such as glass panels, with a heavy duty robotic mechanism to stack substrates in a first in, last out process.

In an embodiment, the present batch carrier comprises a clamping mechanism for holding the substrates stationary, for example, to prevent damage during movement. The clamping mechanism is preferably gravity operated, using a weight to clamp the substrates to the carrier. The gravitation clamping mechanism provides a passive clamping operation, clamping the substrates without active components. At loading or unloading station, a passive feature or an active mechanism can lift the gravitation mechanism, releasing the clamp to allow substrate transfer. In an aspect, the clamping components hold the substrates only at the edges to prevent possible damage to the devices.

In an embodiment, the present batch carrier comprises a slot width reduction mechanism for ease of substrate entry to or exit from the carrier and for reducing substrate movement during transport. The slot width mechanism can be gravity operated, using a weight to move a slot width reduction component. At loading or unloading station, a passive feature or an active mechanism can lift the gravitation mechanism, enlarging the slot width to allow ease of substrate transferring in or out of the batch carrier. During transport, the gravitational mechanism is engaged, reducing the slot width to restrict the side movement of the substrates. The reduced slot width can still be larger than the width of a substrate, allowing for variations in the substrate fabrication and warpage.

In an embodiment, the present invention discloses a batch processing system for processing substrates positioned in a batch carrier. The system comprises a loading station where the carrier is stored, a process chamber to process the substrates in the carrier, and a transfer mechanism to transfer the carrier to the process chamber. The process chamber preferably comprises doors to enclose the process environment, with the transfer mechanism releasing the carrier to the process chamber and thus free for transferring other carriers. The system further includes unloading station for unloading the carrier, carrier storage station for storing extra carriers, and carrier I/O station to exchange carriers to outside the processing system.

In an embodiment, the process chamber comprises a process volume, a holding volume, and a process moving mechanism to move the carrier between the holding volume and the process volume. This can allow the substrates to get in and out of the process volume, for example, to provide some agitation to the process. A door mechanism can contain the process environment, preventing release of process chemicals. The process chamber can have manual access doors for service, for example, to clean or to remove broken substrates.

In an embodiment, the process chamber is designed for wet process, further comprising chemical supply and drainage, which are preferably gravity operated. For example, a chemical supply tank can be located above the process chamber and a drain is located at the bottom of the process chamber. A recirculation system can be included, comprising a filter, a liquid pump and a heater for controlling the chemical temperature.

In an aspect, a plurality of filters is included with a valve manifold for switching between the filters. This can provide an in-situ filter change, allowing uninterrupted processing.

In an embodiment, the process chamber comprises an in-situ cleaning of the recirculation system, for example, to allow uninterrupted processing of substrates. A valve manifold can be provided to the recirculation system, to isolate the recirculation system from the process chamber, and at the same time, providing cleaning chemical to the recirculation system. For example, for an electroless deposition process, the material can be coated everywhere, including the heater and the pump. These components can be isolated for cleaning without interfering with the batch processing service, for example, cleaning during the drainage of chemical or during the filling of chemical to the process chamber.

### BRIEF DESCRIPTION OF THE DRAWINGS

FIG. 1A illustrates an exemplary prior art batch processing system.

FIG. 1B illustrates an exemplary prior art single substrate processing system.

FIG. 1C illustrates an exemplary prior art in-line processing system.

FIG. 2A illustrates an embodiment of the present in-line-batch interface.

FIG. 2B illustrates an embodiment of the present batch-in-line interface.

FIGS. 3A-3D illustrate various configurations for the in-line-batch interfaces

FIG. 4A illustrates an exemplary embodiment of the present batch processing system.

FIG. 4B illustrates another exemplary embodiment of the present batch processing system.

FIG. 5A illustrates an exemplary carrier assembling or disassembling station.

FIG. 5B illustrates another exemplary carrier assembling or disassembling station.

FIGS. 6A-6D illustrate various substrate holding configurations for a robot assembly.

FIGS. 7A-7C illustrate various configurations of interface stations.

FIGS. 8A-8C illustrate a configuration for an interface station with sensors and alignment mechanisms.

FIG. 9A illustrates an exemplary safety mechanism to protect a substrate supported on a robot end effector.

FIG. 9B illustrates an exemplary robot end effector equipped with the safety mechanism.

FIGS. 10A-10B illustrate a sequence of movements of a safety mechanism. FIG. 10A illustrates an extending movement. FIG. 10B illustrates a retracting movement.

FIGS. 11A and 11B illustrate another sequence of movements of safety mechanism.

FIGS. 12A-12D illustrate a sequence of movements of a safety mechanism from a resting position (FIG. 12A) to a protecting position (FIG. 12D).

FIGS. 13A-13B illustrate an exemplary batch carrier supporting substrates in vertical positions.

FIGS. 14A and 14B illustrate a sequence of clamping substrates using a clamping mechanism.

FIGS. 15A and 15B illustrate a sequence of restricting substrate movement using a slot width reduction mechanism.

FIG. 16 illustrates an exemplary batch carrier according to an embodiment of the present invention.

FIG. 17 illustrates an exemplary batch processing system.

FIG. 18A illustrates an exemplary processing station.

FIG. 18B illustrates an exemplary configuration for in-situ cleaning of a recirculation path.

FIG. 19A illustrates an exemplary process flow for interfacing with an in-line input station.

FIG. 19B illustrates an exemplary process flow for interfacing with an in-line output station.

FIG. 20 illustrates an exemplary process flow for interfacing a batch equipment in an in-line facility.

FIG. 21 illustrates another exemplary process flow for interfacing a batch equipment in an in-line facility.

FIG. 22A illustrates an exemplary flow for a safe mechanism protecting the substrates.

FIG. 22B illustrates another exemplary flow for a safe mechanism protecting the substrates during substrate removal from an in-line transport.

FIG. 23 illustrates an exemplary flow of an assembling operation, assembling substrates from an in-line transport to a batch carrier.

FIG. 24 illustrates an exemplary process flow for a robot transferring a substrate to a batch carrier slot.

FIG. 25 illustrates an exemplary flow for a transport robot movement, moving a batch carrier.

FIG. 26A illustrates an exemplary process for flow for substrate conditioning during assembling.

FIG. 26B illustrates an exemplary process for flow for substrate conditioning during disassembling.

FIG. 27 illustrates an exemplary process flow for a transport robot carrying a carrier from an assembling station to a batch process station.

FIG. 28 illustrates a process flow of an exemplary wet process.

FIG. 29 illustrates a process flow of in-situ cleaning of components in the process station.

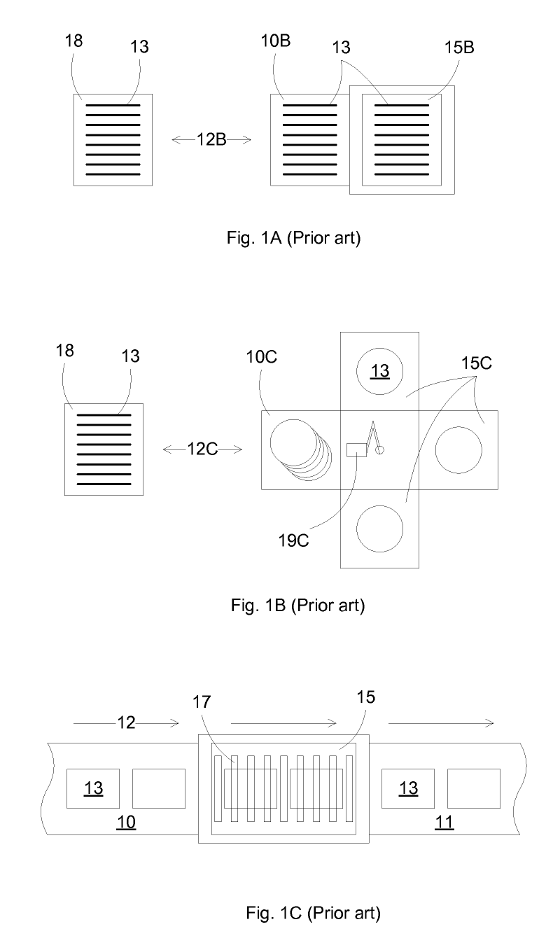

### DETAILED DESCRIPTION OF THE PREFERRED EMBODIMENTS

The present invention relates to methods and systems for a batch processing system for processing multiple substrates stored in a batch carrier. The present invention further pertains to the manufacture of photovoltaic cells and thin film modules, producing photovoltaic junctions. In an embodiment, the present invention deposits a layer on a substrate, by subjecting the substrates to a liquid environment, for example, by electro plating or electroless plating. Other processes can also be performed, such as wet processing of cleaning, rinsing, stripping, texturing, or dry processing of vapor deposition, or annealing. The substrates can be semiconductor substrates such as silicon wafers, or non-semiconductor substrates such as glass panels or polymers (manufacturing of OLEDs). The substrate can be glass substrates, but other substrates, such as single crystal or multicrystalline (or polycrystalline) silicon substrates, metal substrates, or substrates with a semiconductor coating, can also be utilized. The present invention can provide high throughput processing for cost reduction and productivity improvement in photovoltaic cells and related devices.

In an embodiment, the present invention relates to methods and systems for a batch processing system interfacing in-line loading or unloading stations, for example, in a fabrication facility. In-line processing equipment can offer simplified equipment with high throughput, but could be disadvantageous for processes with long processing time. In an aspect, the present batch processing system includes in-line interfaces to be used in an in-line processing facility. The present in-line interface can be at the input, including a carrier assembly station connected to an in-line conveyor belt. The carrier assembly station receives substrates continuously provided from the in-line conveyor belt, and assembles these substrates to a batch carrier to be forwarded to a batch processing station. The present in-line interface can be at the output, including a carrier disassembly station connected to an in-line conveyor belt. The carrier disassembly station picks substrates from a batch carrier and places these individual substrates continuously to the in-line conveyor belt. The present in-line interface can be at the input and the output, including a carrier assembly station and a carrier disassembly station each connected to an in-line conveyor belt.

An advantage of an in-line fabrication facility is the automatic transport of substrates, for example, through a conveyor belt or rollers between process stations. Conventional in-line facilities also include transport of substrates within the process stations. In an embodiment, the present invention provides batch processing capability to an in-line fabrication facility while maintaining the automatic transport of substrates throughout the facility. The inclusion of the present batch system in an in-line facility can be seamless, with the loading and unloading stations linked directly to the in-line transport system without any operator assistance.

In an embodiment, the present invention discloses an interface linking an in-line transport system to a batch transport system. An in-line transport system typically comprises an automatic transport for carrying individual substrates, either one substrate or multiple substrates in one row. A typical in-line transport system is a running conveyor belt on which the substrates are transported at the speed of the conveyor belt. Another typical in-line transport system comprises a plurality of rollers rotating at a same speed for moving substrates. An in-line transport system brings substrates to an in-line process chamber which also includes an in-line transport system to move the substrates through the process chamber.

A batch transport system typically comprises a mechanism moving batch carriers holding multiple substrates. A batch transport system brings batch carriers to a batch process chamber, and delivers the multiple substrates, with or without the batch carrier, to the process chamber.

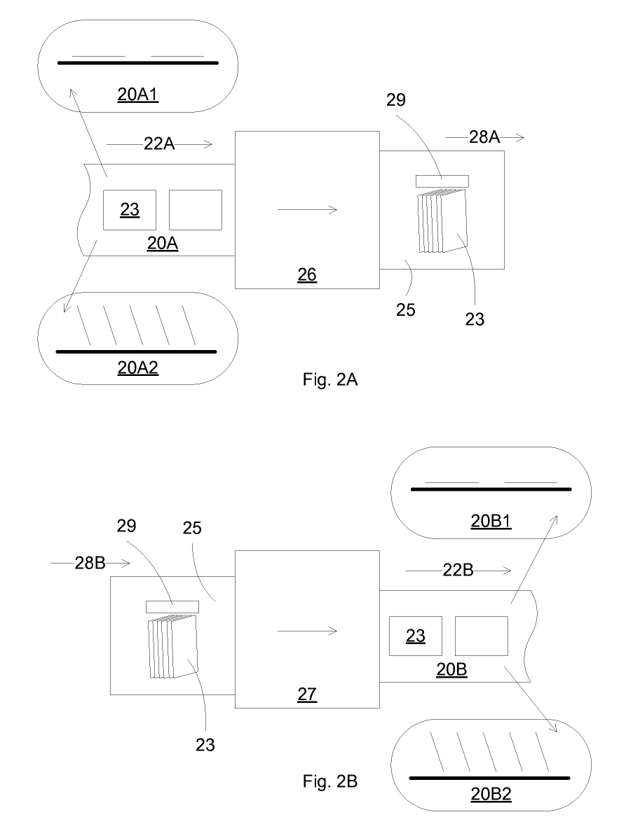

FIG. 2A illustrates an embodiment of the present in-line-batch interface, comprising an assembling station 26, linked to an in-line transport system 20A and a batch system 25. The in-line transport system 20A runs in direction 22A, delivering individual substrates 23 toward the assembling station 26. The substrates can be positioned horizontally on a conveyor belt 20A1, or can be positioned at an angle on the conveyor belt 20A2. The substrates can be in a single row or in multiple rows across the conveyor belt. The assembling station 26 receives the individual substrates 23 and assembles them on multiple batch carriers 29, which are transported in direction 28A toward a batch processing station.

FIG. 2B illustrates an embodiment of the present batch-in-line interface, comprising a disassembling station 27, linking to a batch system 25 and an in-line transport system 20B. The batch system 25 runs in direction 28B, delivering batch carriers 29 supporting multiple substrates 23 toward the disassembling station 27. The disassembling station 27 receives the batch carriers 29, each with multiple substrates 23, disassembles the substrates, and places the individual substrates 23 on the in-line transport system, which are transported in direction 22A toward a destination such as a next processing station.

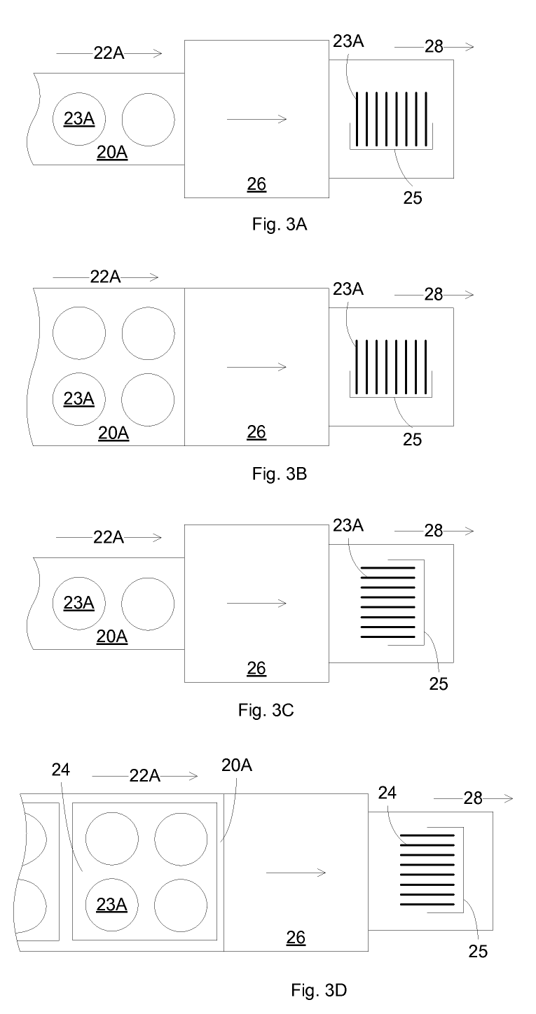

The substrates 23 in these figures are shown to be rectangular solar panels, positioned in one row in the in-line stations 20A and 20B and assembled vertically in batch carriers 29. Other configurations are also possible, such as the configurations shown in FIGS. 3A-3D. FIG. 3A illustrates circular substrates 23A, such as semiconductor wafers, arranged in single row in the in-line station 20A, and assembled vertically in batch carrier 25. FIG. 3B illustrates substrates 23A arranged in two rows in the in-line station 20A, and assembled vertically in batch carrier 25. FIG. 3C illustrates substrates 23A assembled horizontally in batch carrier 25. FIG. 3D illustrates substrates 23A, arranged in multiple and assembled horizontally in batch carrier 25. Configurations for disassembling stations are similar.

In an embodiment, the present invention discloses a batch processing system with loading and unloading stations interfacing in-line stations. The batch system comprises a batch process chamber, designed for simultaneously processing multiple substrates. The batch system also comprises a loading station, linked to an input in-line station for accepting continuous incoming substrates, and assembling multiple substrates in each batch carrier, to be transferred to the batch process chamber for processing. The batch system also comprises an unloading station, linked to an output in-line station for transferring continuous outgoing substrates. The unloading station disassembles the substrates within the batch carriers, and places these individual substrates on the outgoing in-line station. The present batch processing system can be inserted into an in-line transport system, similar to any in-line processing system. The connection is seamless, and the installation of the batch system can be virtually identical to an in-line system.

In an embodiment, the present batch system provides the mix-and-match of equipment in an in-line fabrication facility, allowing the usage of other equipment types, such as batch system or single substrate system, in an in-line facility. This can provide optimization for an in-line facility, allowing the selection of equipment based on performance and cost considerations, instead of consideration based on equipment types.

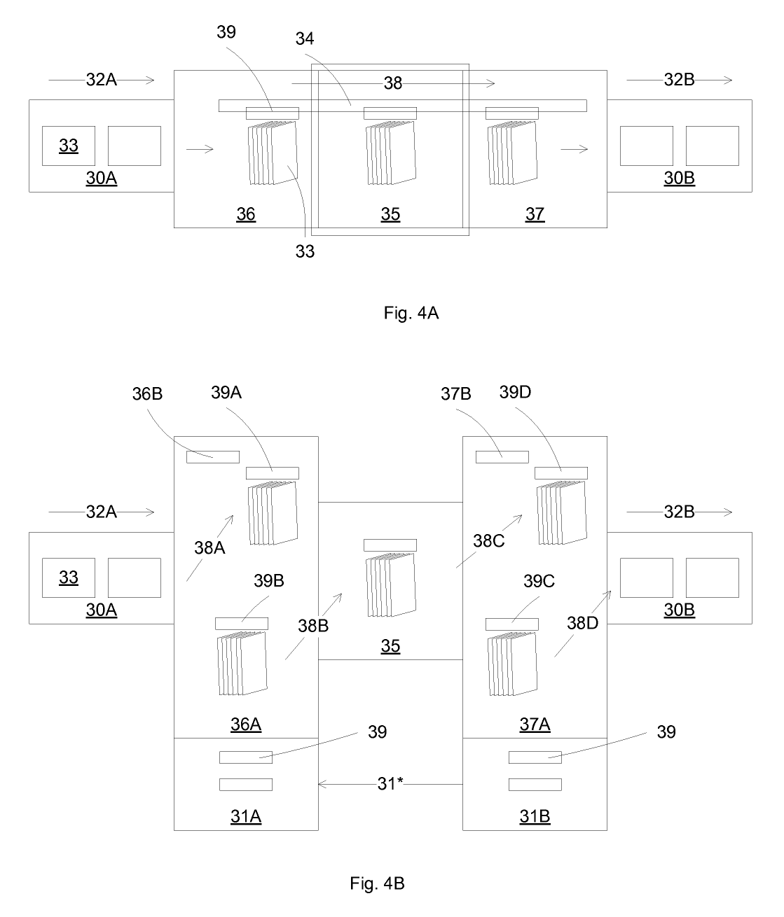

FIG. 4A illustrates an exemplary embodiment of the present batch processing system, comprising a carrier assembly station 36, a batch processing station 35 and a carrier disassembling station 37. The carrier assembly station 36 interfaces an in-line loading station 30A to accept substrates 33 traveling in direction 32A. The in-line loading station 30A can be included in the present batch processing system, or can be provided by the in-line facility, continuously providing substrates 33 to the carrier assembly station 36. Multiple substrates are then assembled onto a plurality of batch carriers 39 in the assembly station 36. The batch carriers 39 can be transported in direction 38, by a carrier transport system 34, between the carrier assembling station 36, the batch processing station 35 and the carrier disassembling station 37. At the processing station 35, the transport mechanism 38 can release the batch carrier into a processing chamber, continue to transport carriers during the batch processing, and return to pick up the carrier after process completion. The processing chamber can comprise a lid to contain the process environment, separating the process chamber from the rest of the system. The carrier disassembly station 37 interfaces an in-line unloading station 30B such as a conveyor belt traveling in direction 32B. Similarly, the in-line unloading station 30B can be included in the present batch processing system, or can be provided by the in-line facility, continuously carrying substrates 33 to the next processing system. In the carrier disassembling station 37, multiple substrates from the batch carriers 39 are individually collected and placed onto the in-line conveyor belt 30B.

The present batch processing system with in-line interface provides a small foot print for processes with long processing time in an in-line facility. For example, for glass substrates of 1 m length, to achieve a throughput of 60 substrates per minute, the in-line conveyor belt would travel at a speed of 1 m/min, thus delivering one substrate every minute. For short processes, for example, a 2 minute process, a process zone of 2 m would be adequate since every area of the substrate is covered by the process zone for 2 minutes. For a long process, for example, a 30 minute process, a process zone of 30 m would be required. Such length is impractical, both by foot print requirement and by uniformity requirements. Thus the present batch processing system provides a practical solution for the in-line facility, addressing processes with long processing time. In an embodiment, the present batch system can interface with the in-line transport system, accepting the substrates and assembling 30 substrates into one batch carrier to be processed simultaneously in 30 minutes, with an average throughput of 1 substrate per minute.

FIG. 4B illustrates another exemplary embodiment of the present batch processing system, comprising a carrier assembly station 36A, a batch processing station 35 and a carrier disassembling station 37A. To reduce the overhead time of assembling and disassembling substrates, multiple carriers can be utilized in the carrier assembling and disassembling stations. For example, when substrates are assembled 38A to a batch carrier 39A, another batch carrier 39B filled with substrates is transferred 38B to the processing station 35. Similarly, when substrates are disassembled 38D from a batch carrier 39C, another batch carrier 39D filled with substrates is transferred 38C from the processing station 35. With multiple batch carriers, the assembling and disassembling times are not contributed to the throughput calculation, thus improving the overall efficiency of the system. In an embodiment, the system further comprises a carrier buffer storage 31A for storing carriers, either emptied carriers or filled carriers. For example, substrates can be assembled onto multiple carriers, which are then waiting in the carrier storage 31A to be processed. Empty carriers can be stored in carrier buffer storage 31A to be supplied to the assembling station 36A. In an embodiment, the system further comprises a carrier IO station 31B for swapping carriers into and out of the system. The carrier IO station can be used to replace carriers, for example, when carriers have been damaged during processing. In an embodiment, the system further comprises a transport system 31* for transporting empty carriers from the output station, e.g., the carrier IO station 31B, back to the input station, e.g., the carrier buffer storage 31A. This can complete the routing of the carrier, returning the empty carriers back to the assembling station 36A after unloading the substrates in disassembling station 37A.

In an embodiment, the system further comprises conditioning systems 36B and 37B for conditioning the substrates. The conditioning system 36B and 37B can be incorporated in the assembling station 36A and the disassembling station 37A, respectively. Assembling and disassembling substrates can be slow, and thus the first and the last substrates after assembling or disassembling might not have the same surface characteristics, such as wetness or dryness. For example, after the batch carrier emerged from a wet process chamber, all substrates are equally wet. However, during disassembling, the first substrate might still be wet, but the last substrate might already be dried, due to the long disassembling time.

In an embodiment, the conditioning system 36B and 37B condition the substrates so that the substrates all have consistent characteristics, such as wetness or dryness, or temperature. For example, the conditioning system can comprise steam or water vapor spray onto the substrates during assembling or disassembling, with or without chamber enclosure, to ensure that the substrates maintain their surface wetness. Or the conditioning system can comprise heaters to dry or heat the substrates to ensure equal dryness or equal temperature during assembling or disassembling.

In an embodiment, the present invention discloses methods and systems for a carrier assembling or disassembling station, assembling individual substrates from an in-line input to one or more batch carriers, or disassembling substrates from batch carriers into individual substrates to an in-line output. The system can comprise a robot assembly for handling the substrates, together with aligning system and sensors for precision handling. The robot assembly can be a multi-axis robot, accepting substrates in a horizontal direction and assembling in a vertical direction, or vice versa. The robot assembly can be a planar robot, accepting and delivering substrates in a same horizontal configuration. The robot assembly can be a mating station, linking the in-line station with the carrier for direct substrate transfer.

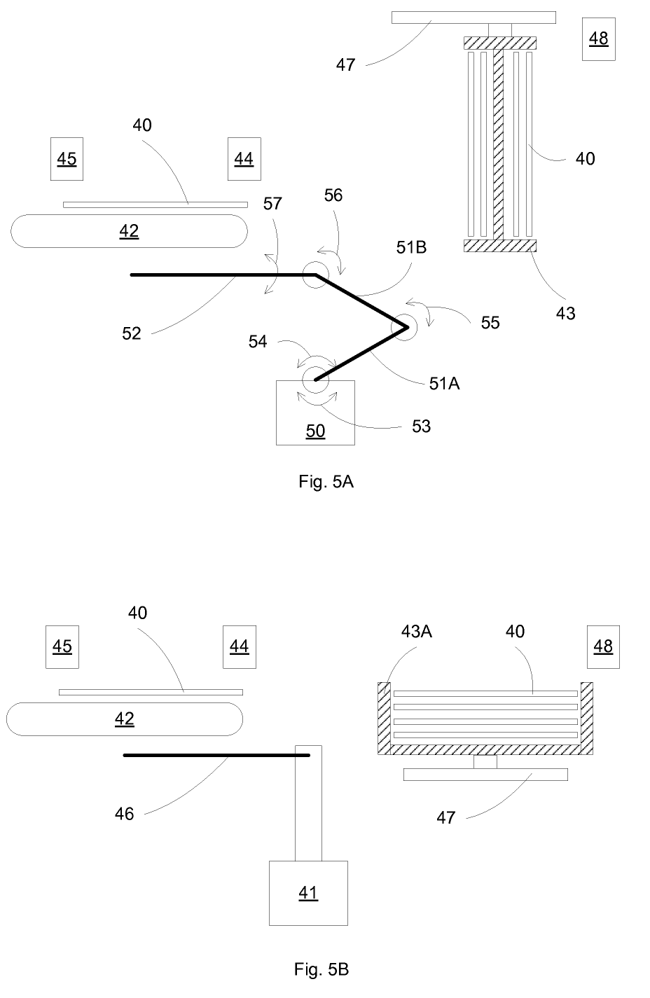

FIG. 5A illustrates an exemplary carrier assembling or disassembling station, comprising a multi-axis robot 50 stationed between an in-line station 42 and one or more batch carriers 43. The multi-axis robot 50 can also be any robotic mechanism for transferring substrates between an in-line station 42 and batch carriers 43. In an aspect, the robot end effector picks up the substrates from the back side, thus preventing damage to the front side where all the active devices are located. Other picking processes can also be implemented, for example, picking from the front side or from the edge of the substrate. The in-line station 42 thus can have a conveyor belt supporting only the edge of the substrates, leaving the middle of the substrate accessible to be picked up. The input in-line station can have sensors 44 to detect the positions of the incoming substrates, and the information from the sensors can be communicated to the robot 41 to allow the robot to adjust its positions to ensure proper alignment. The input in-line station can have an alignment mechanism 45 to align the incoming substrates, for example, rollers or pushers to align the substrates into proper locations to allow the robot to collect them. The batch carrier 43 can support multiple substrates, and preferably supported at both sides of the carrier for balance. For carrier 43 supporting vertical position substrates as shown, the robot 50 positions the end effector to be horizontal under the substrate 40, then lifts up the end effector to support the substrate. A holding mechanism, such as vacuum suction, can be activated to hold the substrate on the robot end effector. The robot then turns around, and flips vertically to slide the substrate onto the carrier 43. With multi-axis robot, the robot can transfer the substrate to the front side and the back side of the carrier by properly rotating the multiple joints on the robot arms. After putting substrates into the batch carrier 43, a carrier transfer mechanism 47 can transfer the carrier to the process station. The carrier can comprise a handling mechanism to allow automatic carrier transfer mechanism 47 to pick up and release the carrier. A conditioning mechanism 48 can be included to provide the same conditions to the substrates entering or exiting the carrier. Multiple batch carriers 43 can be loaded to the carrier assembling or disassembling station to improve the throughput of the processing system.

In an embodiment, the present system employs a multi-axis robot for handling the substrates in the assembling or disassembling station. The multi-axis provides flexibility and ease of construction for the complicated movement of transferring substrates from the in-line station to the batch carrier. The robot comprises a fixed base 50, together with a number of robot arms 51A and 51B, and end effector 52. The robot further comprises a number of joints 53-57 to allow the arms and end effector to reach many positions. For example, joint 53 can provide rotation around an axis perpendicular to the base surface. Joint 54 allows arm 51A to move with respect to the base 50. Joint 55 allows arms 51A and 51B to move with respect to each other. Joint 56 allows end effector 52 to move relative to arm 51B. Joint 57 allows end effector 52 to rotate with respect to arm 51B.

FIG. 5B illustrates another exemplary carrier assembling or disassembling station, comprising a planar robot 41 interfacing a horizontal in-line station 42 and a horizontal carrier. The planar robot 41 comprises an end effector 46, moving in horizontal direction for transferring substrates 40 between the station 42 and the carrier 43A. The robot 41 can have vertical movements to accommodate various locations in the carrier.

In an embodiment, the present invention discloses methods and systems for conditioning the batch carriers in the assembling or disassembling station, for example, to ensure that the substrates in the batch carrier all have the same conditions. In general, it takes some time to assemble and disassemble all the substrates in the carrier, and thus the first and last substrates might be somewhat different. For example, if the batch process is a wet process, the substrates leaving the process station are somewhat wet. In the disassembling station, the first substrate leaving the carrier to the in-line conveyor is still wet, but the last substrate leaving the carrier can be already dry due to the time lapse of transferring multiple substrates. Thus the present invention discloses a conditioning mechanism 48 to provide the same conditions to the substrates leaving the carrier. In an aspect, the conditioning mechanism comprises a wet environment, such as liquid spray, vapor spray, steam spray, liquid, vapor or steam nozzle, to supplement the loss of liquid vapor, or a semi-enclosure surrounding the carrier to minimize the loss of liquid vapor. Alternatively, the conditioning mechanism comprises a dry environment to ensure that all substrates leaving the carrier are dry. The conditioning mechanism can comprise a control temperature environment to provide consistent temperature for the substrates. The conditioning mechanism can be implemented in the assembling station, in the disassembling station, or in both.

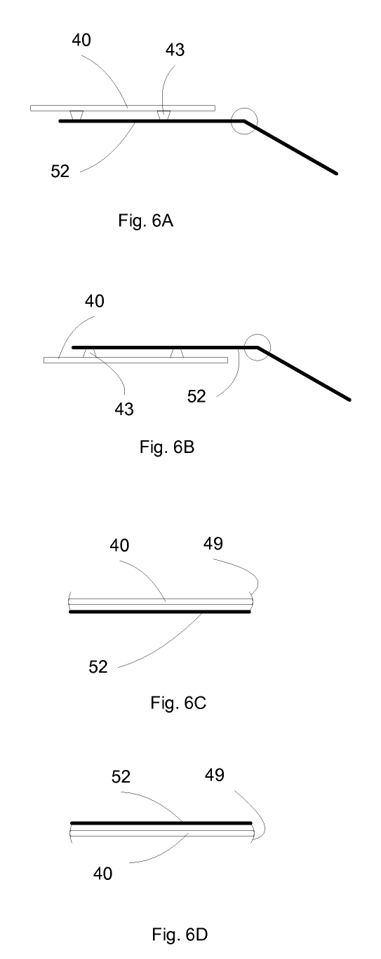

The robot assembly can handle the substrates by different configurations, such as an end effector having vacuum suction or by edge gripper. FIGS. 6A-6D illustrate various substrate holding configurations for a robot assembly, such as comprising an end effector 52 supporting a substrate 40 at the bottom through vacuum suction 43 (FIG. 6A), an end effector 52 supporting a substrate 40 at the top through vacuum suction 43 (FIG. 6B), an end effector 52 supporting a substrate 40 at the bottom through edge grips 49 (FIG. 6C), an end effector 52 supporting a substrate 40 at the top through edge grips 49 (FIG. 6D).

In an embodiment, the present system further comprises an interface station linking to the in-line transport to facilitate the handling of the substrates. For example, to facilitate holding substrates at the bottom, the interface station comprises transfer assembly that exposes a large bottom area of the substrates. For edge gripping robot, the interface station can comprise transfer assembly that exposes the edges of the substrates.

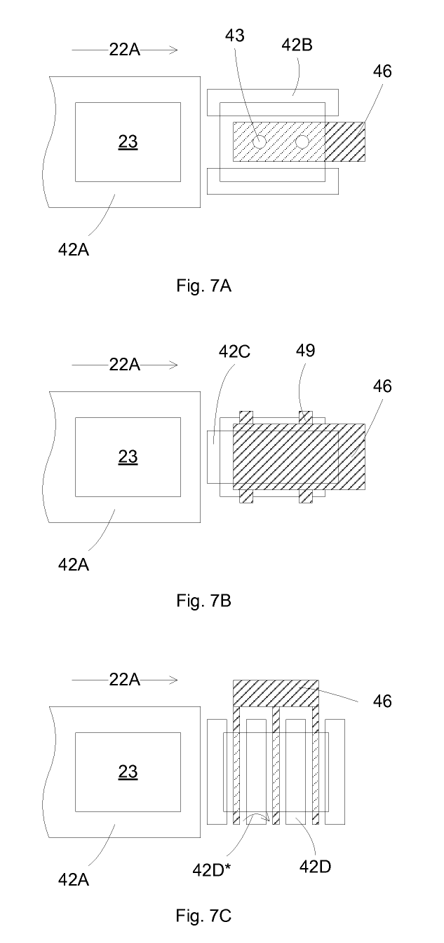

FIGS. 7A-7C illustrate various configurations of interface stations, linking to an incoming in-line conveyor 42A, delivering the substrates 23 toward 22A the interface station. FIG. 7A illustrates an interface station that exposes the back side of the substrates with two conveyor belts 42B running at the two sides of the substrates. When the substrate 23 reaches the end of the conveyor belt 42A, the substrate 23 is transferred to the conveyor belts 42B, carrying the substrate 23 forward. An end effector 46 having vacuum suction 43 is positioned at the back side opening of the substrate to pick up the substrate. FIG. 7B illustrates an interface station that exposes the edges of the substrates by a center conveyor belt 42C. An end effector 46 having edge grips 49 is positioned at the top of the substrate for gripping the substrate edges. FIG. 7C illustrates an interface station that comprises a plurality of rollers 42D rolling the substrate forward 42D*. An end effector 46 having a plurality of fingers can be inserted between the rollers for picking the substrate.

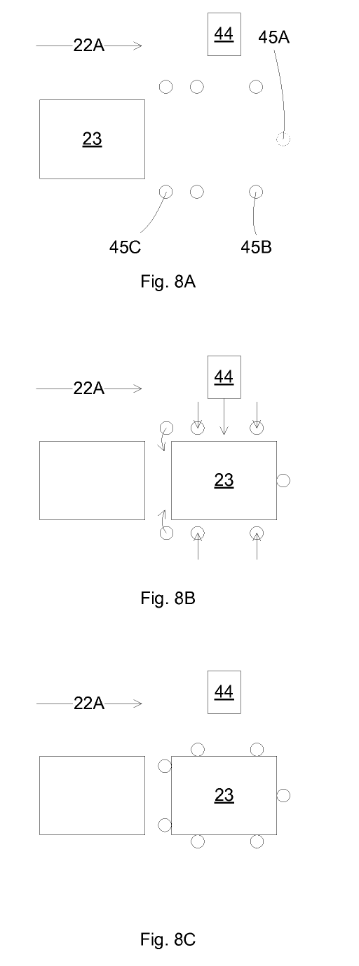

In an embodiment, the interface station comprises sensors and alignment mechanism for precision substrate handling. Sensors can be used to detect the presence of the substrates, and alignment mechanisms can position the substrates to precise locations for robot handling. FIGS. 8A-8C illustrate a configuration for an interface station with sensors and alignment mechanisms. Substrate 23 arrives 22A at the interface station, which has sensor 44 for detecting the presence of the substrate, and various alignment mechanisms 45A, 45B and 45C for aligning the substrate. Upon detecting a coming substrate by sensor 44, alignment pin 45A rises up to limit the forward traveling of the substrate. Alignment pins 45B move forward and alignment pins 45C rotate inward to align the substrate. Other alignment mechanisms and sensor configurations can also be implemented.

In an embodiment, the present invention discloses methods and systems for a safety assembly on the robot to prevent substrate damage. The substrates can be supported by the robot end effector, for example, by vacuum suction or by clamping. The present safety assembly provides an extra level of surety to prevent dropping the substrate, especially if the main substrate support fails. In an aspect, the safety assembly does not touch the substrate, but is separated a short distance from the substrate. The safety assembly can comprise an extending/retracting mechanism, wherein the extending mechanism extends the safety assembly to cover the substrate after the substrate is located on the robot end effector, and the retract mechanism retracts the safety assembly so that the substrate can be removed. The safety assembly can comprise a forward/backward mechanism, wherein the forward mechanism extends the safety assembly from under the substrate to outside the substrate, and the backward mechanism retracts the safety assembly back under the substrate. The movement mechanism of the safety features can be activated by solenoid or pneumatic mechanisms, or any other movement mechanisms.

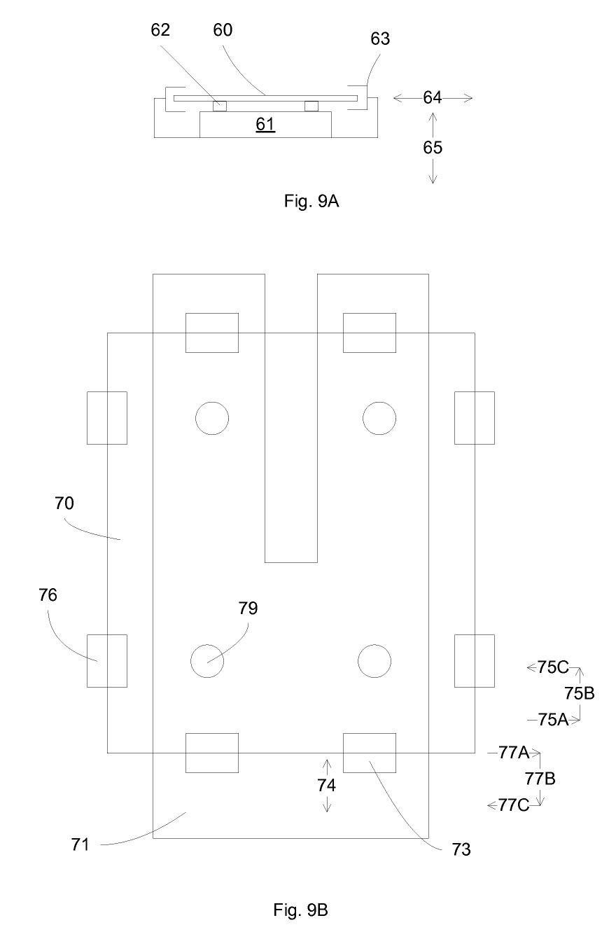

FIG. 9A illustrates an exemplary safety mechanism to protect a substrate supported on a robot end effector. As shown, the substrate 60 is held on robot end effector 61 by a vacuum mechanism 62. The safety mechanism 63 covers the substrate 60 but does not touch the substrate. Safety mechanism 63 protects the substrates from falling away from the robot 61 during movement of the robot, especially if the vacuum mechanism 62 fails. For example, when the robot turns to keep the substrate vertical for sliding into a carrier, the vacuum mechanism 62 holds the substrate onto the robot. The safety mechanism 63 covers the substrate so that if the vacuum fails, the substrate would be caught by the safety mechanism and would not leave the robot arm. The non-touch feature prevents any possible damage to the devices, and the safety mechanism provides an additional safeguard against losing expensive substrates. In an aspect, the safety mechanism 63 can move along the substrate direction 64 or to direction 65 perpendicular to the substrate. These movements allow the safety mechanism to extend/retract/forward/backward as needed to accommodate other design criteria.

FIG. 9B illustrates an exemplary robot end effector equipped with the safety mechanism. An end effector 71 supports a substrate 70 by a main support mechanism 79 such as a plurality of vacuum suctions. In an aspect, there are two types of safety mechanisms 73 and 76. The safety mechanism 73 can be mounted on the top surface of the end effector, outside of the substrate area, and can extend and retract in the direction 74. The safety mechanism 76 can be mounted on the bottom surface of the end effector and for covering the substrate, can extend 75A outside the substrate area, forward 75B to the top surface, and retract 75C to cover the substrate. For removing the safety coverage, for example, when moving the substrate to a carrier, the safety mechanism 76 can extend 77A outside the substrate area, backward 77B to the return to the bottom surface, and retract 77C under the end effector. The different safety mechanisms are designed to accommodate lifting the substrate out of the in-line station. For example, the substrate is supported by a conveyor belt located along the length of the end effector, and therefore the safety mechanism 76 needs to be located under the end effector.

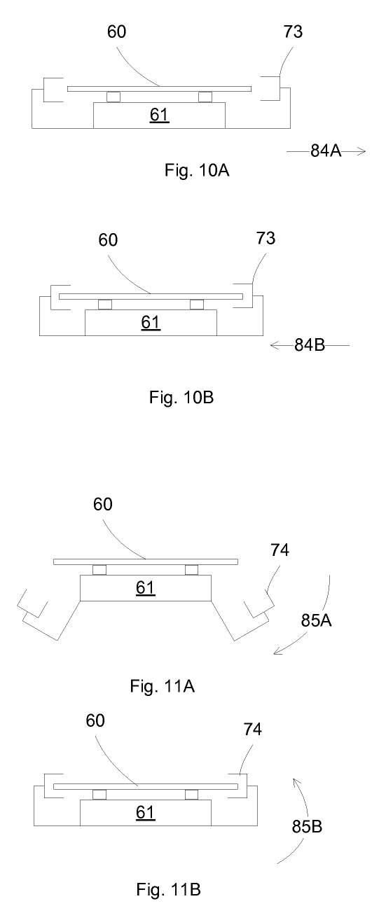

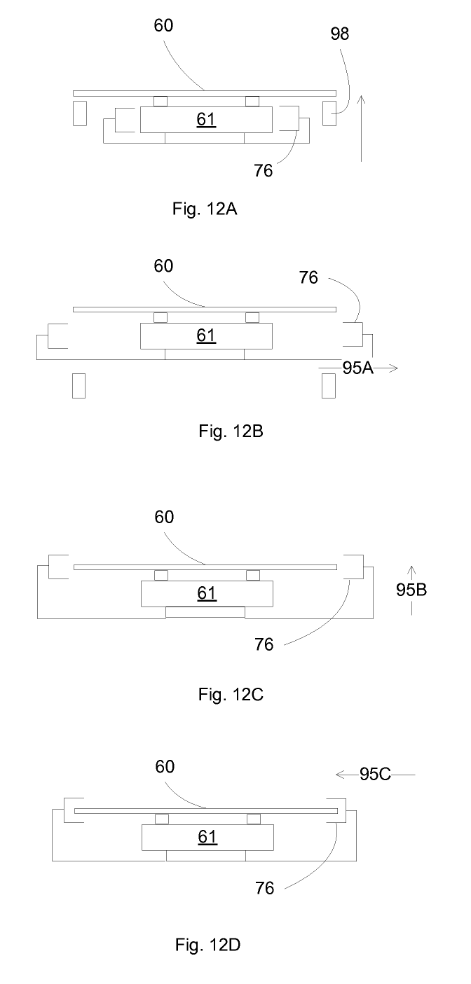

FIGS. 10A and 10B illustrate a sequence of movements of safety mechanism 73. There is no space constraint at this side of the substrate, so that the safety mechanism 73 can be mounted at the same plane as the substrate 60. Safety mechanism 73 thus is mounted outside of the end effector 61 and at the same plane as the substrate 60. FIG. 10A illustrates an extending movement 84A of the safety mechanism 73 outside the substrate area. In this position, the substrate can be removed. FIG. 10B illustrates a retracting movement 84B of the safety mechanism 73 to cover the substrate. In this position, the substrate is protected against accidentally dropping from the robot, for example, in events of vacuum suction failure.

FIGS. 11A and 11B illustrate another sequence of movements of safety mechanism 74. Safety mechanism 74 can be mounted inside of the end effector. FIG. 11A illustrates a downward rotational movement 85A of the safety mechanism 74. In this position, the substrate can be removed. FIG. 11B illustrates an upward rotational movement 85B of the safety mechanism 74 to cover the substrate. In this position, the substrate is protected.

FIGS. 12A-12D illustrate a sequence of movement of safety mechanism 76 from a resting position (FIG. 12A) to a protecting position (FIG. 12D). In FIG. 12A, the end effector 61 supports the substrate 60 and the safety mechanism 76 is positioned under the substrate. In FIG. 12B, the safety mechanism 76 extends from under the substrate to outside the substrate area in direction 95A. In FIG. 12C, the safety mechanism 76 moves forward from under and outside the substrate to above (and outside) the substrate area in direction 95B. In FIG. 12D, the safety mechanism 76 retracts from outside the substrate to protecting the substrate in direction 95C. To remove the substrate, the sequence is reverse, from the protecting position of FIG. 12D to the resting position of FIG. 12A. The safety mechanism 76 allows the substrate to be supported at the side, for example, by a conveyor belt 98, since the end effector (and the safety mechanism 76) is located well inside the substrate area.

The safety mechanism is thus engaged during robotic movement to protect the substrate from possible damage due to any modes of failures. The safety mechanism is disengaged before loading substrate onto the robot end effector, or before unloading the substrate from the robot end effector to either the in-line conveyor belt or to the batch carrier. The engagement/disengagement of the safety mechanism can be gradually, e.g., one safety after another after some time delay, or can be together, e.g., all safety together at the same time, depending on situations of the substrate and the availability of substrate supports.

In an embodiment, the present invention discloses methods and systems for a batch carrier supporting multiple substrates. The batch carrier can comprise a metal frame covered with a polymer coating for protection against corrosive chemicals. The batch carrier can comprise handler for robotic transfer between stations, such as from carrier loading/unloading stations to process stations. The batch carrier can comprise supports having fingers or slots for separating the substrates, which can be stored horizontally or vertically. The supports can be at the bottom and sides of the substrates.

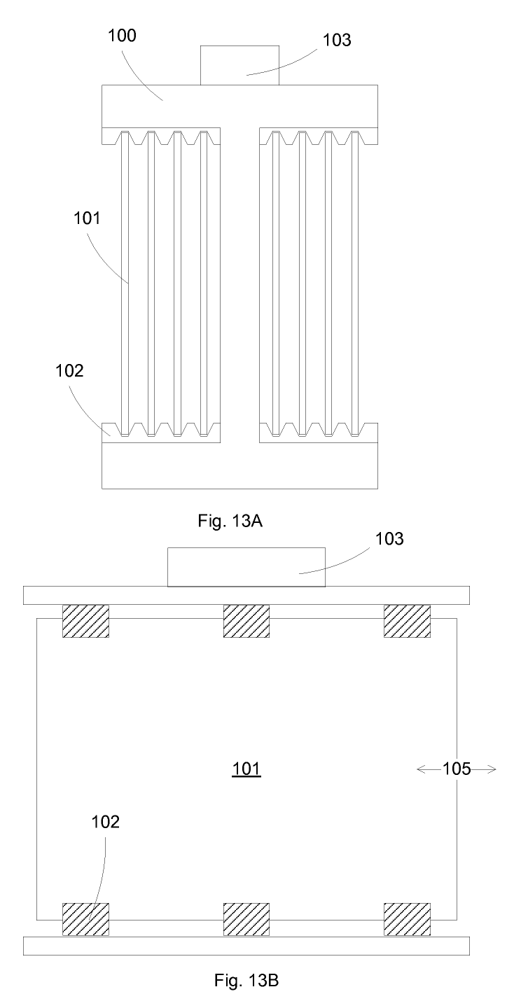

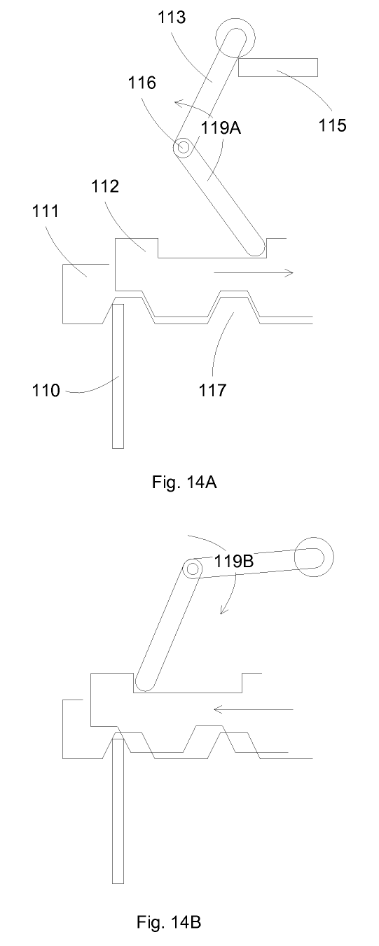

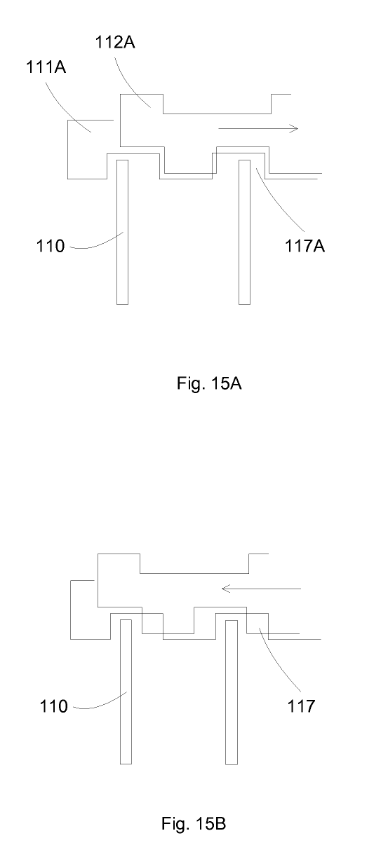

FIGS. 13A-13B illustrates an exemplary batch carrier supporting substrates in vertical positions. Batch carrier 100 can hold a number of substrates 101, separated by the fingers or slots 102. To transfer substrate 101 in and out of the batch carrier, the substrate 101 can be slide along direction 105 following the fingers or slots 102. The batch carrier can comprise a handling mechanism 103 for moving by an automatic transport.

In an embodiment, the present invention discloses methods and systems for clamping substrates in a batch carrier, for example, to prevent movements which can generate damages or particles. The batch carrier thus can comprise a clamp mechanism for securing the substrates during transport. The clamp mechanism is disengaged during the loading or unloading of substrates. The substrates can be supported by one or more supports, together with one or more clamp mechanism for securing the substrates. The clamp mechanism can act on the slot opening of the substrate support, thus providing a large slot during loading and unloading for easy substrate transfer, and small slot size (e.g., clamping on the substrate) during carrier transport. In an aspect, the clamp mechanism is gravity driven, thus passively activated only during transport. At resting position for loading and unloading, a support feature can push against the clamp mechanism, releasing the clamp for loading and unloading. Alternatively, active clamping, such as pneumatic or motor driven, can be applied.

FIGS. 14A and 14B illustrate a sequence of clamping substrates using a clamping mechanism. The clamping mechanism can comprise stationary component 111, moving component 112 and a rotating component 113 rotatable with respect to an axis 116. Rotating component 113 is designed to be heavy and will rotate downward in direction 119B by gravity if not blocked. When rotating downward, rotating component 113 will translate the rotating action to linear action of moving component 112 to push component 112 against component 111. FIG. 14A illustrates a clamping mechanism in a disengaged state at a resting position, leaving the slot 117 open for easy loading and unloading substrates. In this position, the rotating component 113 is rotating upward in direction 119A and is supported by a support feature 115. The rotating component 113 pushes the moving mechanism 112 backward to open slot 117. FIG. 14B illustrates a clamping mechanism in engaged state, for example, at moving position. When leaving the resting position, the support feature 115 is no longer supporting rotating component 113, and gravity rotates the rotating component 113 in downward direction 119B. Rotating component 113 in turn pushes moving component 112 forward, clamping substrates 110 against the stationary component 111. The stationary component 111 and the moving component 112 can have slant angle so that the substrate 110 is only clamped at the edge. This gravity clamping mechanism can be passive, requiring no active components, and can protect the substrates against vibration or movement during carrier transport. Other gravity operated clamping mechanism can be implemented, for example, only a rotating component, operated by gravity, pushes against a stationary component to clamp the substrates. For example, components 112 and 113 can be integrated into one piece. In addition, an active clamping mechanism can also be used, such as, but not limited to, a motorized clamp or pneumatic clamp.

In an embodiment, the present invention discloses a slot width reduction mechanism for restricting the substrate movements during transport and processing. The slot width reduction can be considered as a form of substrate clamping, which restricts the substrate movement and also accommodates the differences in substrate characteristics, such as thickness, size or warpage variations. For example, the clamping mechanism does not necessarily clamp the substrate, but fixes it in narrower slots which provide sufficient guidance during transport and processing. During substrate transferring in and out of the batch carrier, the slot width is enlarged, for example to facilitate substrate movements. During batch carrier transport, e.g., between IO stations and process station, or during substrate processing, the slot width is reduced, for example, to restrict the lateral movements of the substrates.

Due to the tolerance of the substrates, for example, the substrate can be partially bent or warped, an expanded slot is needed to pass the substrates within the slots. In addition, due to the variations of substrate tolerance, contact clamping which applies adequate forces to a substrate might apply too high or too low mechanical forces to other substrates. For example, adequate forces for straight substrates could be too high for bent substrates.

In an embodiment, the clamping mechanism has V-shape for clamping the substrates with edge contact. In another embodiment, the camping mechanism has straight U-shape with non-contact clamping. The substrates might have different height, subjected to the tolerance specifications, and thus when using V-shape clamps, there can be difference in clamping forces for different substrates. For example, the larger substrates would get clamped while the smaller substrates would remain loose. A U-shape clamp mechanism would accommodate the difference in substrate height.

The enlarged slot width can be a few mm larger (e.g., 2-10 mm larger, or can be about 5 mm larger) to accommodate the sliding of substrates in or out of the carrier. The reduced slot width can be about the width of the substrate, or can be slightly larger to accommodate for the variations in substrate manufacturing (e.g., thickness, size or warpage). For example, the reduced slot width can be a few mm larger (e.g., 0-5 mm larger) than the width of the substrate.

FIGS. 15A and 15B illustrate a sequence of restricting substrate movement using a slot width reduction mechanism. The slot width reduction mechanism comprises two components 111A and 112A which move relative to each other, e.g., component 111A can be stationary and component 112A moving, component 111A moving and component 112A stationary, or both components moving. The components 111A and 112A comprise slot 117A for holding substrates 110. FIG. 15A illustrates the components 111A and 112A in disengaged position, leaving slots 117A enlarged to allow ease of moving substrates 110 in and out of the carrier. For example, the component 112A moves away, maximizing the slot width 117A. FIG. 15B illustrates the components 111A and 112A in engaged position, reducing the slot width of slots 117A to restrict movements of substrates 110 within the carrier. For example, the component 112A moves toward component 111A, minimizing the slot width 117A.

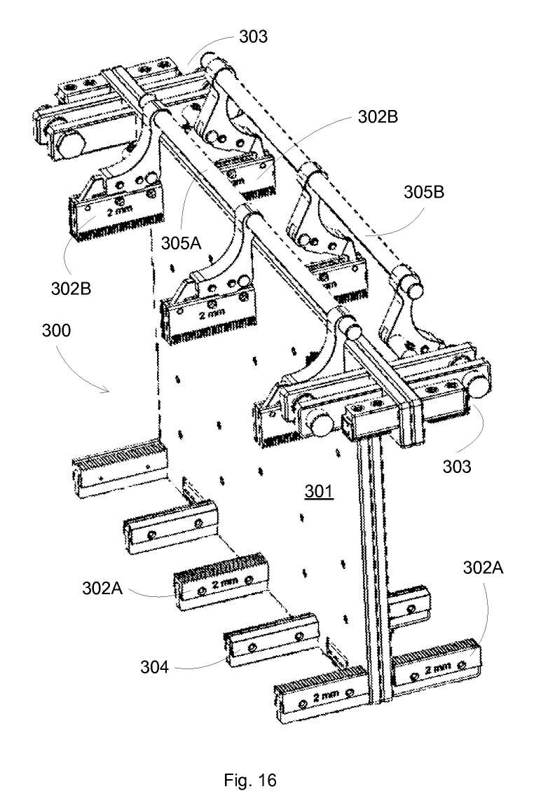

FIG. 16 illustrates an exemplary batch carrier according to an embodiment of the present invention. The batch carrier 300 comprises a vertical plate support 301 with handling mechanisms 303 for transporting the batch carrier 300 between different locations. The batch carrier 300 further comprises a plurality of bottom slot components 302A and top slot components 302B, each having a plurality of slots to accommodate the substrates. The slot components 302A and 302B are disposed on both sides of the vertical plate support 301, allowing the substrates to be stored on both sides of the plate support 301. Optional substrate supports 304 can be included to support the substrates. The substrate supports 304 can be flat, or can have shallower slot depth than the slot components 302A and 302B, and are typically installed at the bottom portion to support the substrates. The batch carrier 300 further comprises clamps 305A and 305B, such as a V-shape clamp, U-shape clamp, contacting clamp, or non-contacting clamp such as slot width reduction mechanism. As shown, clamp 305A is in engaged position, with the clamp bar lower and the slot width reduced. Clamp 305B is in disengaged position, with the clamp bar raised and the slot width enlarged. The shown clamp mechanism is a gravitational type, using gravity to engage the clamp. For example, at a loading or unloading station, the clamp bar is raised, for example, by a push mechanism, allowing the substrate to be loaded and unloaded with ease. When releasing the push mechanism, the clamp bar is automatically lower due to gravity, engaging the clamp mechanism, for example, reducing the slot width.

In an embodiment, the present invention discloses methods and systems for a batch processing system, comprising a batch loading station, one or more process stations, a batch unloading station, and a transport robot to transport a batch carrier between these stations. In an aspect, the transport robot can retrieve a carrier of substrates from a loading station, and deposit in a process station to be processed. After complete processing in one process station, the transport robot can transfer the carrier to another process station, or to the unloading station for substrate removal. In an aspect, the loading station and the unloading station can be the same station.

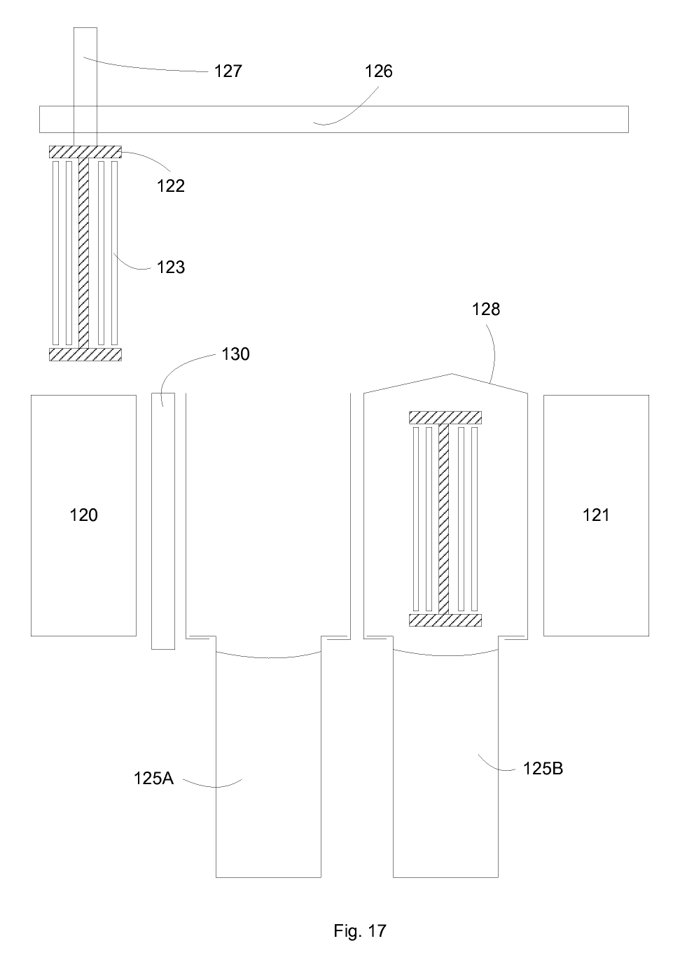

FIG. 17 illustrates an exemplary batch processing system, comprising a loading station 120, an unloading station 121, and a plurality of process stations 125A-125B, together with a transport robot 126 to transfer a batch carrier 122 between these stations. The batch carrier 122 can support a plurality of substrates 123. The substrates 123 are shown in vertical positions, preferably for wet processing. Other configurations of the substrates and batch carrier can also be implemented, such as horizontal substrate configuration. The transport robot 126 can also include a vertical lifting mechanism 127 to lift the batch carrier 122 out of a station and to deposit the batch carrier to another station. In an exemplary process sequence, the transport robot 126 extends the vertical lifting mechanism to the loading station 120, engaging a batch carrier 122. The vertical lifting mechanism 127 then retracts, bringing the batch carrier 122 to a position to be transferred to other stations. The transport robot 126 then transports the batch carrier 122 to a first processing station 125A. The processing station 125 (FIG. 16A) has the lid doors 128 open to accept the batch carrier. The vertical lifting mechanism then deposits the batch carrier into the process station 125A, and the lid doors 128 closes to contain the process environment. The other process station 125B has similar configuration, for similar and parallel processing, or have different configurations for different process demands. Alternatively, the lid doors might not close for certain processes, for example, a substrate rinsing process or a substrate wetting process where there is no problem of exposure. Also, some process stations might not have lid doors. After complete processing, the batch carrier 122 is deposited in the unloading station 121 for substrate removal, for example, to a next process.

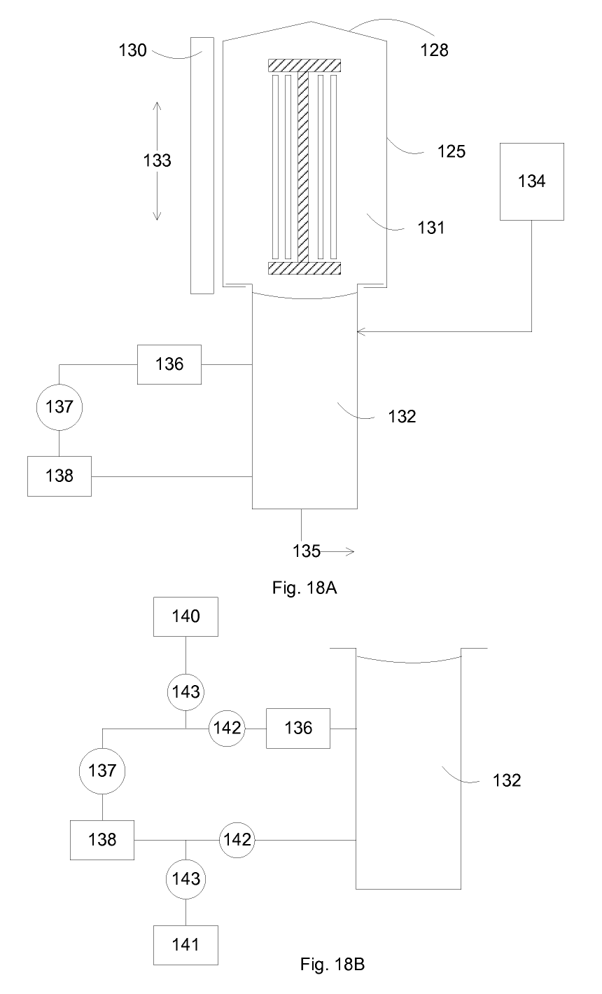

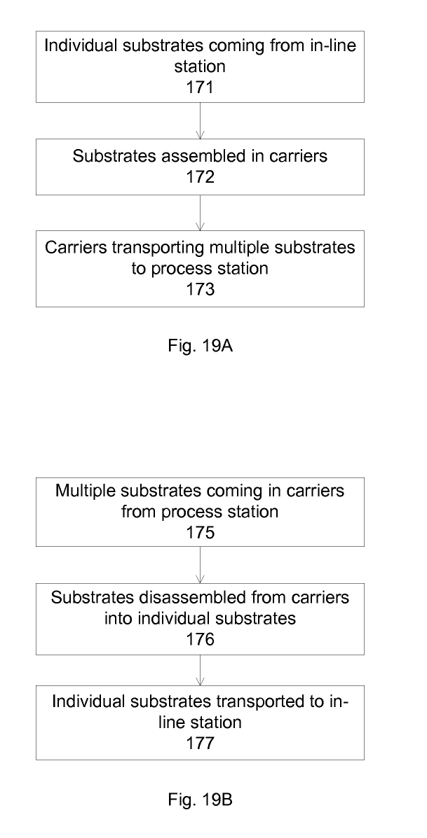

In an embodiment, the present invention discloses methods and systems for a process station. FIG. 18A illustrates a holding chamber 131, a processing chamber 132, and a robot 130 to transfer a batch carrier between the two chambers. The process station can comprise a lid door 128 to contain the process environment, for example, to contain the vapor of the liquid in the processing chamber and to facilitate the exhaust of the processing environment. The process chamber 132 is filled with chemicals for wet processing the substrates stored in the batch carrier. The holding chamber 131 can comprise nozzles to deliver gas, liquid, or gas/liquid mixture to the substrates. For example, the nozzles can deliver rinsing liquid, such as water, to clean and rinse the substrates after finishing processing in the process chamber 132. The rinsing liquid can be aerated, e.g., a mixture of gas and liquid. The rinsing liquid can be heated, with added surfactant. The nozzles can deliver chemicals for pre-processing or post-processing, in addition to the wet processing in the process chamber 132. The nozzles can sequentially deliver cleaning chemicals, treating chemicals, and rinsing chemicals to the substrates. After a batch carrier 122 (see FIG. 17) carrying substrates 123 (see FIG. 17) is deposited to the process station 125, the robot 130 engages the batch carrier 122 so that it can transfer the batch carrier within the process chamber. In general, the transport robot 126 (see FIG. 15), after reaching the process chamber 125, transfers the handling of the batch carrier 122 to the robot 130. The transport robot 126 then retracts, and can move to another position to transport other batch carriers.

In an embodiment, the process station 125 is designed for wet process, with processing chamber 132 filled with liquid chemical. The robot 130 can move the batch carrier 122 up and down in direction 133 in and out the liquid of the processing chamber 132. Repeated movement of robot 130 can provide the agitation of the liquid environment, for example, to generate a turbulence of the liquid to stir and mix the liquid. The robot 130 can move the batch carrier in and out of the liquid, for example, from the processing chamber 132 to the holding chamber 131. Alternatively, the robot 130 can move the batch carrier up and down within the liquid, so that the substrates are still submerged in the liquid even when the robot 130 moves up.

In an embodiment, the process station 125 also comprises chemical delivery assembly and chemical circulation assembly. The chemical delivery assembly comprises a plurality of chemical tanks 134 to deliver fresh chemical to the processing chamber 132. The chemical tank 134 is preferably positioned at a higher elevation than the processing chamber so that the chemical can fill the processing chamber by gravity force. The chemical delivery assembly can also include a drainage system to drain the chemical after process completion. The drain is preferably located at the bottom of the processing chamber, and the drain pipes directed downward to use gravity for draining the chemical. The chemical delivery assembly can include valves and manifold to facilitate chemical refill or storage. Other configurations can also be implemented, for example, by using a pump to deliver chemical to the processing chamber, or using another pump to drain the chemical from the processing chamber.

A chemical recirculation assembly can recirculate the chemical in the processing chamber, comprising a pump 137 together with necessary piping, valves and manifolds. A heater 138 can be included in the recirculation path to heat the chemical to a desired temperature. A filter 136 can be included in the recirculation path to remove particulates or any debris from the processing chamber. The recirculation assembly can regulate the temperature of the processing chamber, for example, through the heater, or can clean the chemical through the filter.

In an aspect, the chemical from tank 134 fills the processing chamber with fresh chemical before submerging a batch carrier. The batch carrier can move up and down to provide some agitation and turbulence to the liquid environment. The circulation path keeps the chemical clean and at the right temperature. After completing the process, a new batch carrier can be introduced, and the process continues using the same chemical. Alternatively, the chemical is drained, and a new chemical is introduced before a new batch carrier is deposited in the process station.

In an embodiment, the present invention discloses methods and systems for in-situ cleaning of the components of the process station. For example, for a deposition process, such as an electroless deposition, material can be deposited everywhere, from inside the processing chamber to the pipes, manifolds and components. Without a removal process, these deposits can interfere with the process conditions, and might require system shut down for cleaning and reconditioning before resuming substrate processing. Thus in an aspect, the present invention discloses an in-situ clean process, cleaning the components of the process station to ensure process performance, and without shutting down the system. In an aspect, the present in-situ clean occurs not during processing time, but during the overhead time of process, such as during the chemical change (e.g., draining the old chemical and refilling with new chemical), during carrier change (e.g., removing carrier from the process station and depositing new carrier to the process station), during idle time (when the process station does not process substrates), or during some additional delay time introduced by the system to ensure adequate time for the in-situ cleaning process.

Before the in-situ cleaning process, critical components are identified, for example, the pump 137 and the heater 138 are selected to be cleaned more often than the rest of the components. Piping manifolds with valves are then introduced to allow the isolation of these components, together with linking these components to a cleaning assembly. Thus for an in-situ cleaning process, the cleaning components are isolated from the process station, a cleaning process is carried out (for example, by introducing cleaning chemical and rinse fluid), and the components reconnected back to the process station. The cleaning process preferably occurs automatically, without any operator interference, and/or at any predetermined times or events. Complete shut down for whole system cleaning might still be needed to clean other components, such as the processing chamber, but with the in-situ cleaning process, complete cleaning might be less frequently required.

FIG. 18B illustrates an exemplary configuration for in-situ cleaning of a recirculation path. An isolation manifold, comprising valves 142, is imposed on the recirculation path to isolate the desired cleaning components, such as the pump 137 and the heater 138. A cleaning manifold, comprising valves 143, is introduced to the isolated section to provide cleaning chemical to these components. Before activating the cleaning process, the isolation manifold is activated, for example, by shutting valves 142. Isolation path, comprising pump 137 and heater 138, is then isolated from the process station. Cleaning manifold 143 is then open, allowing cleaning chemical from cleaning tank 140 to pass through the isolation path to a collection tank 141. A recirculation path for the cleaning chemical can be implemented for reusing the cleaning chemical. After cleaning completion, a rinse liquid might be introduced to rinse the isolation path. Optional reconditioning chemical can be introduced to subject the isolation components back to suitable conditions for continued processing. For example, if the process is electroless plating with NH₃, fresh NH₃ might be circulated through the isolation path to condition the pump and the heater with the same chemical as before the cleaning process. Other in-situ cleaning configurations can be implemented, for example three-way valves can be used to both isolate and connect to the cleaning path, or a complete cleaning assembly may be installed to quickly and efficiently clean the isolation section during the time allotted. Alternatively, manual cleaning might be used to clean these components.

The filter 136 might be periodically replaced to ensure consistent process performance. Double filter system with switching manifold can be implemented in the recirculation path to switch filters without interrupting the process.

In an embodiment, the present invention discloses methods for substrate batch processing in an in-line fabrication facility, which can allow mixing equipment in an in-line facility, such as installing batch equipment, single substrate processing equipment, or any other types of process equipment in an in-line facility. The present method and equipment can provide a seamless incorporation of equipment, with the installation process virtually indistinguishable from the in-line equipment.

In an embodiment, the present invention discloses an interface station, linking a non-in-line equipment to an in-line station, such as an in-line transport system, or an in-line process station. The interface station can be at an input station, at an output station, or at both input and output stations.

FIG. 19A illustrates an exemplary process flow for interfacing with an in-line input station according to an embodiment of the present invention. Operation 171 accepts individual substrates coming from an in-line station, such as an in-line conveyor belt transporting substrates in an in-line fabrication facility. Operation 172 assembles the incoming individual substrates in carriers, for example, 6, 13, 25, or 50 substrates in a carrier. The number of substrates in a carrier depends on the substrate characteristics, such as, but not limited to, size and weight, and also depends on throughput considerations. The assembling can be performed by a robot, such as multi-axis robot for ease of changing substrate orientation, or planar axis robot for simplicity. Alignment can be included for precision assembling. Substrate conditioning can also be included to ensure that all substrates have the same conditions and characteristics in the carrier. Multiple assembling stations can be provided for better throughput. Operation 173 transports the carriers containing multiple substrates to a process station. The process station can be a batch process station where all substrates in a carrier are processed simultaneously. The process station can be a single substrate process station where the substrates in a carrier are processed sequentially.

FIG. 19B illustrates an exemplary process flow for interfacing with an in-line output station according to an embodiment of the present invention. Operation 175 transports the carriers containing multiple substrates out of a process station. The substrates can be transported in the process carriers, or can be transferred to the transport carriers. Operation 176 disassembles the multiple substrates in the carriers into individual substrates and places these substrates onto an in-line station, such as an outgoing conveyor belt. Substrate conditioning can also be included to ensure that all substrates have same conditions and characteristics after transfer from the carrier. Multiple disassembling stations can be provided for better throughput. Operation 177 transports the individual substrates in the in-line station to a next processing station.

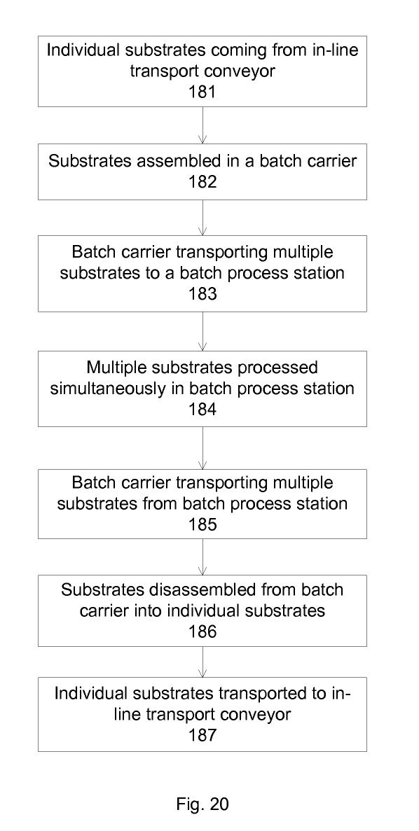

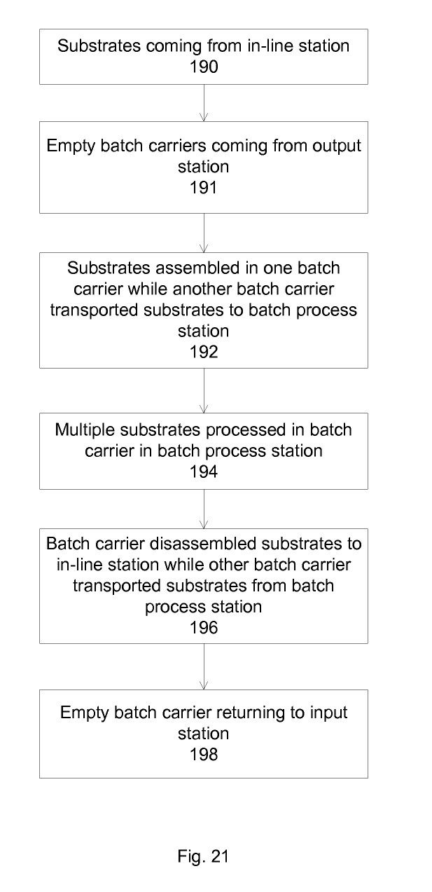

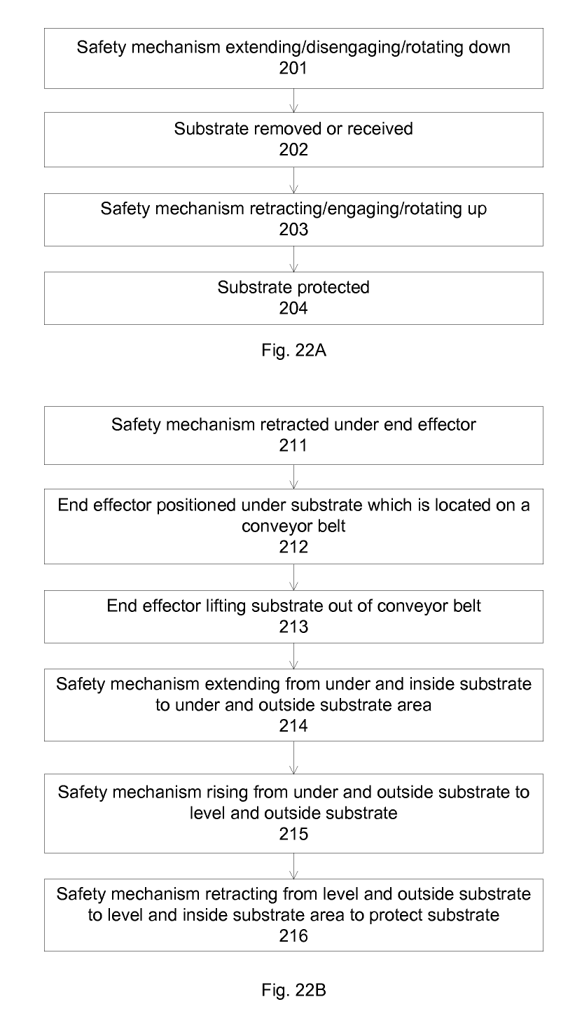

FIG. 20 illustrates an exemplary process flow for interfacing a batch equipment in an in-line facility according to an embodiment of the present invention. Operation 181 accepts individual substrates coming from an in-line station. Operation 182 assembles multiple incoming individual substrates in a batch carrier. Alignment, conditioning and multiple assembling stations can be included. Operation 183 transports the batch carrier containing multiple substrates to a batch process station. The substrates can be transferred to a process carrier, or can stay in the batch carrier for batch processing. Operation 184 processes the multiple substrates simultaneously in the batch process station. Operation 185 transports the carriers containing multiple substrates out of the batch process station. The substrates can be transported in the process carriers, or can be transferred to the transport carriers. Operation 186 disassembles the multiple substrates in the carriers into individual substrates and places these substrates onto an in-line station, such as an outgoing conveyor belt. Substrate conditioning and multiple disassembling stations can also be included. Operation 187 transports the individual substrates in the in-line station to a next processing station.

FIG. 21 illustrates another exemplary process flow for interfacing a batch equipment in an in-line facility according to an embodiment of the present invention. Operation 190 accepts individual substrates coming from an in-line station. Operation 191 accepts empty batch carriers coming from an output station. The batch carriers move from the input assembling station to the output disassembling station, and thus a return loop can be included to bring the batch carriers back from the output disassembling station. Alternatively, new empty batch carriers can be injected to the output station for replacing or for adding new batch carriers. Operation 192 assembles multiple incoming individual substrates in a batch carrier while another batch carrier filled with substrates is transported to a batch process station. Complete assembled carriers can be stored waiting to be carried to the batch process station. Alignment and conditioning can be included during substrate assembling operation. After transporting the batch carrier filled with substrates to a batch process station, the multiple substrates are processed simultaneously in operation 194. After processing, operation 196 transports the carriers containing multiple substrates out of the batch process station. During that time, other carriers filled with substrates are disassembled into individual substrates and these substrates are placed onto an in-line station. Other batch carriers can be waiting to be disassembled. Substrate conditioning can also be included to ensure that the substrates waiting to be placed to the in-line transport line maintain the same desired conditions and characteristics, such as wetness or temperature. Operation 197 transports the empty batch carrier to the input assembling station.

In an embodiment, the present invention discloses a method for protecting the substrates during robot handling without damaging the substrates. The substrate protection comprises a non-touch safety mechanism, designed to catch the substrates if the substrates fall. For example, the substrates can be attached to the robot arm by vacuum suction during transfer from the in-line transport to the batch carrier. In the event of failure, for example, loss of vacuum or broken seal, the substrates can fall off of the robot arm, especially during a substrate rotational action. The present non-touch safety mechanism, such as a non-touch hook or catch, can catch the substrates and support them with the robot arm, preventing substrate breakage.

FIG. 22A illustrates an exemplary flow for a safe mechanism protecting the substrates according to an embodiment of the present invention. Operation 201 disengages the safety mechanism before removing or receiving the substrate in operation 202. The safety mechanism can be disengaged by outward extension, from the position protecting the substrate to the position outside the substrate. The safety mechanism can be disengaged by rotating downward, from the position protecting the substrate to the position under the substrate. Other configurations can be included, such as extending and moving downward. Conversely, operation 203 engages the safety mechanism after receiving the substrate to protect the substrate in operation 204. The engagement movements can include retracting inward, rotating upward, or any other movements.

FIG. 22B illustrates another exemplary flow for a safety mechanism protecting the substrates during substrate collection from an in-line transport, according to an embodiment of the present invention. Operation 211 retracts the safety mechanism under the end effector of the robot. The refraction is designed to hide the safety mechanism under the end effector so that the surface of the end effector is smaller than the surface of the substrate, allowing the end effector to be positioned under the substrate for collecting the substrate. Operation 212 positions the end effector under the substrate, which is located on an in-line transport or an interface to an in-line transport. For example, the substrate is supported by two conveyor belts running on two sides of the substrate, leaving the bottom of the substrate exposed. In operation 213, the end effector lifts the substrate out of the conveyor belts. In operation 214, the safety mechanism extends from under and inside the substrate to under and outside the substrate. In operation 215, the safety mechanism rises from under and outside the substrate to be leveled with and outside the substrate. In operation 216, the safety mechanism retracts from being leveled and outside the substrate to being leveled and inside the substrate. The substrate is then protected and the end effector moves to the intended destination, such as rotating and sliding the substrate to the batch carrier. Placing a substrate on an in-line transport is reversed.

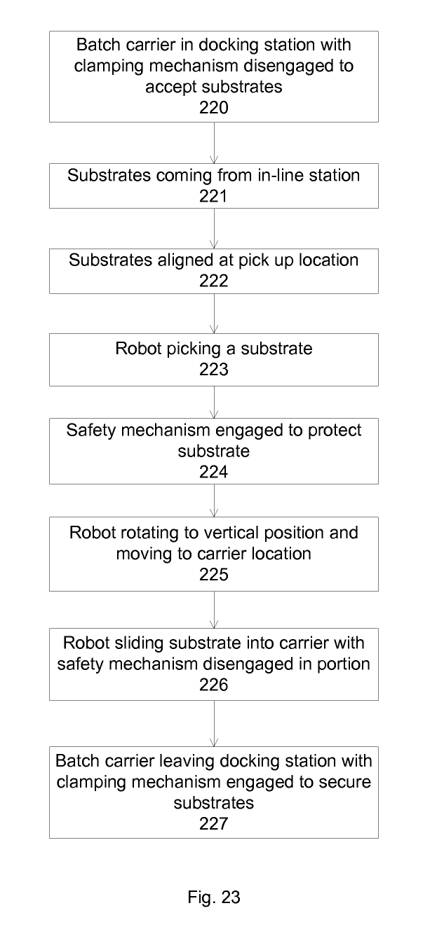

FIG. 23 illustrates an exemplary flow of an assembling operation, assembling substrates from an in-line transport to a batch carrier. In operation 220, a batch carrier is in docking station with a clamping mechanism disengaged to accept substrates. The clamping mechanism can be gravity operated, automatically disengaged when the batch carrier is at the docking station. In operation 221, individual substrates are coming from an in-line station, such as an in-line transport conveyor belt. In operation 222, the substrates are aligned at the pick up location, such as a special interface station designed for aligning substrates and to facilitate picking up substrates by an end effector. In operation 223, a robot picks up a substrate, for example, with the end effector using vacuum suction. In operation 224, a safety mechanism is engaged to protect the substrate, for example, during the subsequent rotational movement. In operation 225, to robot moves to the carrier location while rotating the substrate. In operation 226, the robot slides the substrate into the carrier slot when disengaging the safety mechanism. After all substrates have been transferred, in operation 227, the batch carrier leaves the docking station with the clamping mechanism automatically engaged to secure the substrates from vibrating.

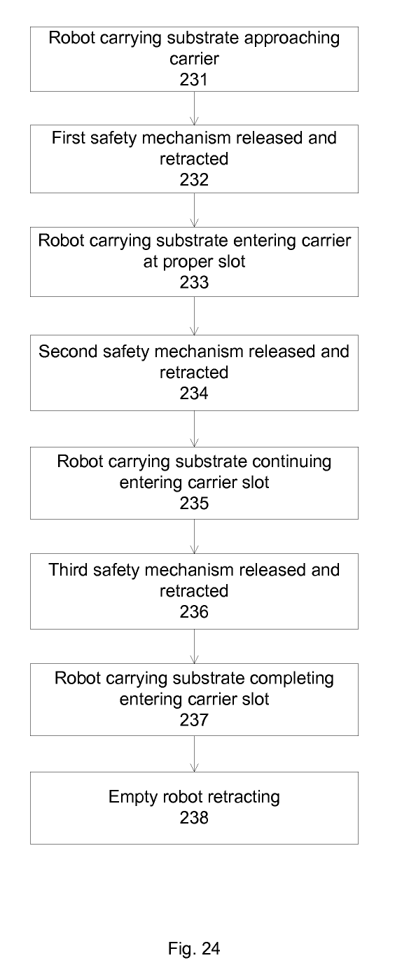

FIG. 24 illustrates an exemplary process flow for a robot transferring a substrate to a batch carrier slot according to an embodiment of the present invention. The safety mechanism can be disengaged gradually when the substrate enters the carrier slot, in order to protect the substrate until being secured in the carrier. In operation 231, the robot carrying a substrate approaches the batch carrier. In operation 232, a first safety mechanism disengaged, for example, by releasing and retracting. With multiple safety mechanisms, the substrate is still protected even when a first set is released. In operation 233, the robot brings the substrate into the proper carrier slot, passing the first safety mechanism and before the second safety mechanism. In operation 234, a second safety mechanism released and retracted, and the robot continues sliding the substrate into the carrier slot in operation 234. In operation 234, a second safety mechanism released and retracted, and the robot continues sliding the substrate into the carrier slot in operation 235. In operation 236, a third safety mechanism released and retracted, and the robot finishes sliding the substrate into the carrier slot in operation 237. The present flow describes three safety mechanisms, but other number of safety mechanisms can be used. In operation 238, the empty robot retracts. The operation can be repeated for bringing other substrates to the carrier.

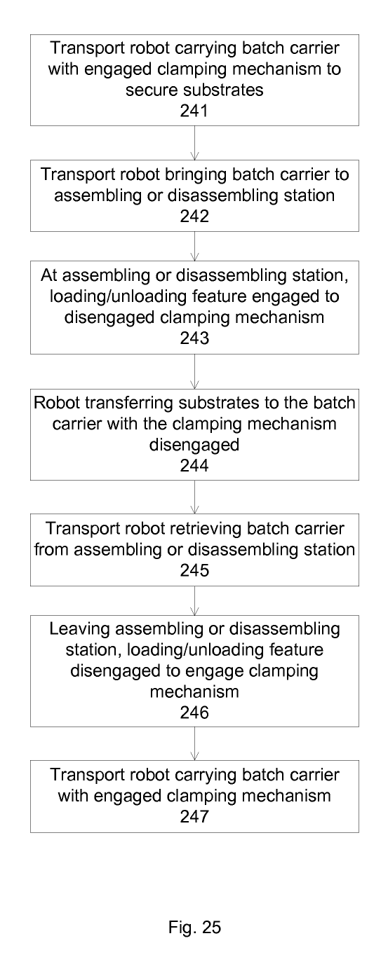

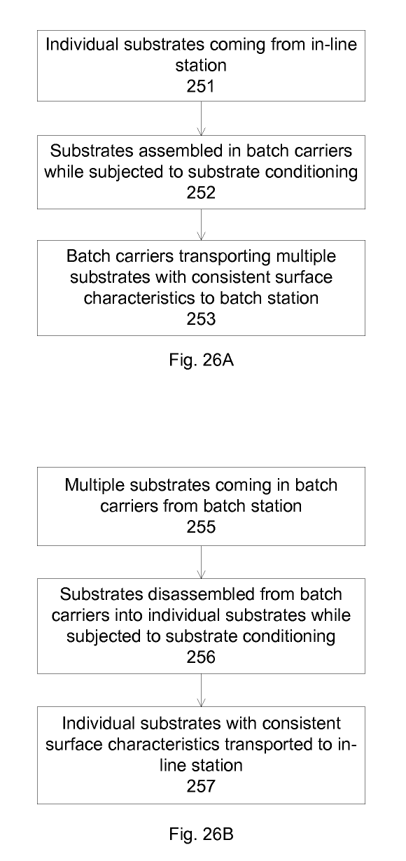

In an embodiment, the present invention discloses an exemplary flow for a carrier transport to bring carriers between stations within the batch equipment. FIG. 25 illustrates an exemplary flow for a transport robot movement, moving a batch carrier. In operation 241, the transport robot carries the batch carrier between stations, with the clamp mechanism engaged to secure the substrates, for example, against vibration. In operation 242, the transport robot brings the carrier to an assembling (or disassembling station). In operation 243, a loading (or unloading) feature is engaged to disengage the clamping mechanism at the assembling (or disassembling) station. In operation 244, transfer robot transfers substrates to (or from) the batch carrier. The clamping mechanism is disengaged to allow access to the carrier slots. In operation 245, the transport robot transports the filled carrier from the assembling (or disassembling) station. When leaving the assembling (or disassembling) station, the loading (or unloading) feature is disengaged to engage the clamp mechanism (operation 246). In operation 247, the transport robot moves the carrier with the clamp mechanism engaged to secure the substrates.

In an embodiment, the present invention discloses a method for conditioning the substrates during assembling, disassembling, or during waiting period. For example, during disassembling after a wet process, the last substrate might be dried out since there will be a time delay between the first substrate and the last substrate. Or when the batch carrier is waiting at the disassembling station, the substrates might be dried out. Thus the present conditioning process can maintain consistent conditions and characteristics to the substrates when entering or leaving the in-line transport.

FIG. 26A illustrates an exemplary process for flow for substrate conditioning during assembling. In operation 251, the individual substrates come from an in-line station. In operation 252, the substrates are subjected to a surface conditioning, such as a controlled environment of liquid spray or heater during assembling into a batch carrier. In operation 253, the batch carrier transports multiple substrates with consistent surface conditions and characteristics to the batch process station. In addition, in multiple assembling stations, waiting carriers with substrates can be subjected to the conditioning operation to ensure consistent characteristics when the transport robot picks up the batch carrier.

FIG. 26B illustrates an exemplary process for flow for substrate conditioning during disassembling. In operation 255, the multiple substrates come from a batch station. In operation 256, the substrates are subjected to a surface conditioning during disassembling into an in-line station, such as an in-line conveyor belt for transporting the individual substrates to a next process station. In operation 257, the in-line transport system transports individual substrates with consistent surface conditions and characteristics to the next process station. In addition, in multiple disassembling stations, waiting carriers with substrates can be subjected to the conditioning operation to ensure consistent characteristics when being disassembled.

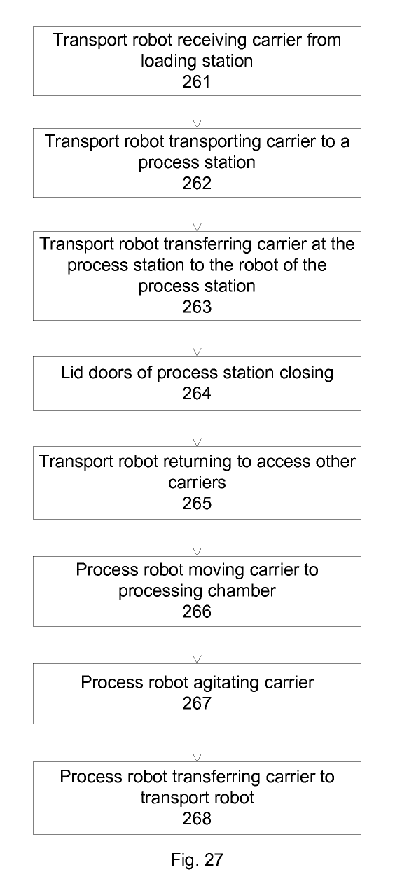

In an embodiment, the present invention discloses a wet batch process for multiple substrates stored in a batch carrier. FIG. 27 illustrates an exemplary process flow for a transport robot carrying a carrier from an assembling station to a batch process station. In operation 261, a transport robot accepts a batch carrier from a loading station, for example, from an assembling station after the substrates have been transferred to the batch carrier. In operation 262, the transport robot brings the batch carrier to a batch process station. When arriving at the process station, lid doors of the process station opens. In operation 263, the transport robot delivers the batch carrier to a process robot. In operation 264, the lid doors close and the batch carrier can be pre-processed in the holding chamber. In operation 265, the transport robot, after delivering the carrier to the process robot, returns to the loading station to accept another carrier. In operation 266, the process robot moves the carrier from the holding chamber to the process chamber, agitating the carrier (in operation 267) in a wet process operation. When completing processing, the process robot moves the carrier out of the process chamber to the holding chamber to be optionally post-processed, such as post-treatment or chemical rinsing. After post-processing, the lid doors open, and the process robot moves out of the process chamber, and delivers the carrier to the transport robot to be transported to the unloading station, such as the disassembling station.

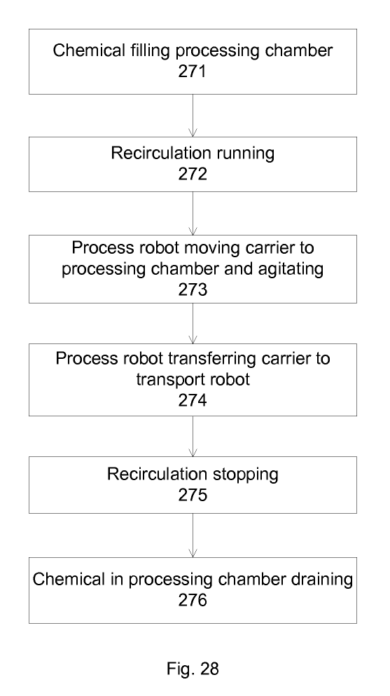

In an embodiment, the present invention discloses a wet batch process for processing multiple substrates in a batch carrier. FIG. 28 illustrates a process flow of an exemplary wet process according to an embodiment of the present invention. In operation 271, process chemicals fill the process station. In operation 272, a recirculation assembly is running to circulate the chemicals in the process station. In operation 273, the process robot moves the carrier filled with substrates to the holding chamber for pre-processing and then to the process chamber 132 for wet processing with carrier. After completing wet processing, before unloading from the process chamber 132, the substrates are lifted to the holding chamber 131 for post-processing, for example, pre-rinsing with DI water by nozzles which are integrated in the lid doors 128. In operation 274, after completing processing, the process robot brings the carrier to a transport robot. In operation 275, the recirculation stops, and the process chemicals in the process chamber is drained (operation 276).

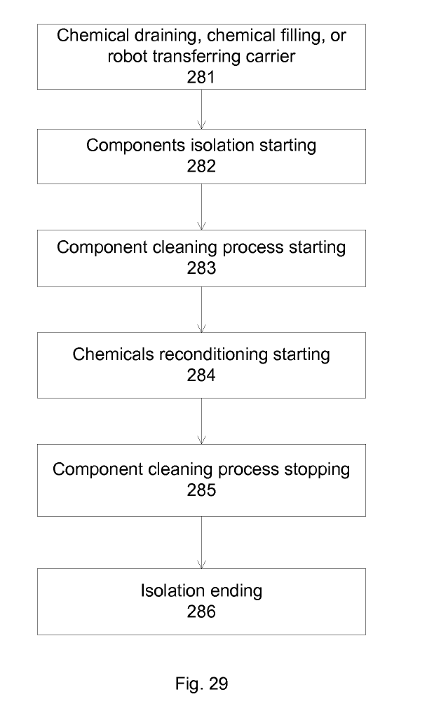

In an embodiment, the present invention discloses a method for in-situ cleaning of the liquid components leading to the process chamber. FIG. 29 illustrates a process flow of in-situ cleaning of components in the process station. In operation 281, during chemical drain, chemical fill, or during transport robot moving carrier, the cleaning components start its isolation to isolate the process chamber from the components to be cleaned (operation 282). After isolation, the component cleaning process starts in operation 283. During or after cleaning, chemical conditioning starts to condition the process in operation 284. In operation 285, cleaning process stops. In operation 286, the isolation ends and the process chamber is ready for processing the next batch of substrates.

While the present invention has been described with respect to a preferred mode thereof, it will be apparent that numerous alterations and modifications will be apparent to those skilled in the art without departing from the spirit of the invention. As to all such obvious alterations and modifications, it is desired that they be included within the purview of my invention, which is to be limited only by the scope, including equivalents, of the following appended claims.

What is claimed is:

1. An interface station for linking process equipment to an in-line transport system, comprising:
a batch process station;
a transfer module coupled to the batch process station and linked to the in-line transport system, the transfer module either
accepting individual substrates coming from the in-line transport system, and assembling multiple substrates to a batch carrier to be processed simultaneously in the batch process station, or
disassembling multiple substrates within a batch carrier coming from the batch process station, and transferring individual substrates outgoing to the in-line transport system.

2. An interface station as in claim 1 wherein the transfer module comprises a robot assembly to assemble the substrate to the batch carrier or to disassemble the substrates from the batch carrier.

3. An interface station as in claim 1 further comprising a conditioning module to condition the substrates such that the substrates all have similar characteristics.

4. A batch process system for operating in an in-line fabrication facility, comprising:
a batch process station;
an assembling station coupled to the batch process station and linked to an incoming in-line transport system, the assembling station accepting individual substrates coming from the incoming in-line transport system, and assembling multiple substrates to a batch carrier to be processed simultaneously in the batch process station;
a disassembling station coupled to the batch process station and linked to an outgoing in-line transport system, the disassembling station disassembling multiple substrates within a batch carrier coming from the batch process station, and transferring individual substrates to the outgoing in-line transport system.

5. A batch process system as in claim 4 wherein at least one of
the assembling station comprises multiple loading stations wherein in one loading station, the substrates are assembled in a batch carrier, and in another loading station, the assembled substrates in another batch carrier are transported to the batch process station, and
the disassembling station comprises multiple unloading stations wherein in one unloading station, the substrates are disassembled from a batch carrier, and in another unloading station, the substrates in another batch carrier are transported from the batch process station.

6. A batch process system as in claim 4 further comprising a returning mechanism to return empty batch carrier from the disassembling station to the assembling station.

7. A batch process system as in claim 4 further comprising a conditioning mechanism coupled to at least one of the assembling and disassembling station for conditioning the substrates.

8. A batch process system as in claim 4 further comprising at least one of sensors and alignment mechanisms for precision assembling of substrates.

9. A batch process system as in claim 4 wherein at least one of
the assembling station comprises a robot having an end effector for accepting substrates from the incoming in-line transport system and for assembling substrates to a batch carrier, and
the disassembling station comprises a robot having an end effector for disassembling substrates from a batch carrier, and for transferring substrates to the outgoing in-line transport system.

10. A batch process system as in claim 9 wherein the end effector comprises a non-touch safety mechanism for protecting the substrate.

11. A batch process system as in claim 4 wherein the batch carrier comprises an I shape with slots to accommodate substrates in a vertical position.

12. A batch process system as in claim 4 wherein the batch carrier comprises an automatic gravity-driven clamping mechanism to reduce the slot width holding the substrates when the batch carrier is not in loading or unloading position

13. A batch process system as in claim 4 further comprising a transport mechanism for transporting the batch carrier between the assembling station, the batch process station and the disassembling station.

14. A batch process system as in claim 13 further comprising a process mechanism for transporting the batch carrier between the transport mechanism and a batch process chamber.

15. A method for operating in an in-line fabrication facility, comprising:
accepting individual substrates coming from an incoming in-line transport system;
assembling multiple substrates to a batch carrier;
transporting the batch carrier having multiple substrates to a batch process station to be processed simultaneously in the batch process station;
disassembling multiple substrates within the batch carrier coming from the batch process station; and
transferring individual substrates to an outgoing in-line transport system.

16. A method as in claim 15 further comprising at least one of
simultaneously assembling substrates to a batch carrier and transporting another batch carrier to the batch process station, and
simultaneously disassembling substrates from a batch carrier and transporting another batch carrier from the batch process station.

17. A batch process system as in claim 15 further comprising returning empty batch carriers after disassembling to be assembling.

18. A batch process system as in claim 15 further comprising conditioning the substrates during at least one of assembling and disassembling.

19. A batch process system as in claim 15 further comprising engaging a non-touch safety mechanism for protecting the substrate when accepting the substrates.

20. A batch process system as in claim 15 further comprising automatic clamping of the substrates in the batch carrier when transporting the batch carrier.
